(19) United States
(12) Patent Application Publication
(10) Pub. No.: US 2013/0191587 A1
(43) Pub. Date: Jul. 25, 2013

(54) MEMORY CONTROL DEVICE, CONTROL METHOD, AND INFORMATION PROCESSING APPARATUS

(71) Applicant: Renesas Electronics Corporation, Kawasaki-shi (JP)

(72) Inventor: Sunao TORII, Kanagawa (JP)

(73) Assignee: Renesas Electronics Corporation, Kawasaki-shi (JP)

(21) Appl. No.: 13/745,781

(22) Filed: Jan. 19, 2013

(30) Foreign Application Priority Data
Jan. 19, 2012 (JP) 2012-009186

(51) Int. Cl. G06F 12/08; G11C 7/10

(52) U.S. Cl. CPC G06F 12/0811; G11C 7/1072
USPC 711/105; 711/122

(57) ABSTRACT

A memory control device includes a first memory, a second memory, a third memory longer in a delay time since start-up until an actual data access, and a control unit. The second memory stores at least a part of data from each data string among multiple data strings with a given number of data as a unit. The third memory stores all of data within the plurality of data strings therein. If a cache miss occurs in the first memory, the control unit conducts hit determination of a cache in the second memory, and starts an access to the third memory. If the result of the hit determination is a cache hit, the control unit reads the part of data falling under the cache hit from the second memory as leading data, reads data other than the part of data, of a data string to which the part of data belongs, from the third memory, and makes a response as subsequent data to the leading data.

### CROSS-REFERENCE TO RELATED APPLICATIONS

The disclosure of Japanese Patent Application No. 2012-009186 filed on Jan. 19, 2012 including the specification, drawings, and abstract is incorporated herein by reference it its entirety.

### BACKGROUND

The present invention relates to a memory control device, a control method, and an information processing apparatus, and more particularly to a memory control device, a control method, and an information processing apparatus, which control an access to a hierarchical memory.

As compared with an improvement in the speed of a processor, an improvement in the speed of an external memory is restricted. For that reason, it is general that a processor core is intimately coupled with a cache memory to input or output data at high speed, thereby conducting data processing. However, the cache memory of this type is required to conduct high-speed operation, and therefore a capacity of the cache memory is restricted. Also, it is general that a dedicated cache memory is provided for a single processor core. Usually, the cache memory of this type is called “first level cache”. Further, an example in which a hierarchical cache (hierarchical memory) such as a second level cache or a third level cache is incorporated into the processor as a cache having a larger capacity is increased. This ensures a given capacity while sacrificing a high speed property to some extent, to thereby lessen a gap between the latency or throughput of the external memory, and an internal processing ability.

In this example, the hierarchical cache creates one solution to an increase in the capacity for improving a cache hit ratio, a decrease in access speed caused by the increase in the capacity, and an increase in electric power. In general, in the hierarchical cache, the capacity is decreased more instead of the high speed operation as the hierarchy is higher in level. Conversely, the capacity of the hierarchical cache is increased more instead of the low speed operation as the hierarchy is lower in level. John L. Hennessy, David A. Patterson, Computer architecture: a quantitative approach Fourth Edition, p 291 sec. 4, P292, FIG. 5.3 discloses a basic structure of the hierarchical cache as illustrated in FIG. 24. The hierarchical cache illustrated in FIG. 24 includes a small and fast L1 cache together with a large and middle-speed L2 cache. With this configuration, even if a miss occurs in the L1 cache, data is supplied from the L2 cache without accessing to a main storage (lower speed than the L2 cache), to thereby reduce a latency.

Also, the first level cache, the second level cache, and the third level cache, or the second and third level caches and an interface that controls an external memory are coupled with each other by an on-chip interconnect network. Further, the second and third level caches may be configured as shared resources of a plurality of cores depending on the configuration of a chip. Since the second and third level caches are accessed if a miss occurs in the first level cache, any advantage is difficult to obtain unless a memory capacity sufficiently larger than that of the first level cache is ensured. On the other hand, the second and third level capacities are not required to provide the access performance of higher speed than that of the first level cache. For that reason, in an SoC (system on a chip) such as an embedded system used for a mobile terminal, there arise such problems that the second level cache is required to provide a large memory capacity, and the costs and a leakage power increase.

Japanese Unexamined Patent Publication No. 2009-288977 discloses a technique pertaining to a cache memory control device. FIG. 25 is a block diagram illustrating a configuration of a cache memory control device 91 in Japanese Unexamined Patent Publication No. 2009-288977. In the present specification, only a related art portion of the present invention will be described. First, a core 9101 makes a read request for necessary data to a controller 9102 through an MI port 9110. Then, the controller 9102 searches a tag memory 9112 which is a cache memory according to the read request. If a cache miss occurs, the controller 9102 instructs a MAC 9115 to conduct data transfer, through an MI buffer 9113. The MAC 9115 acquires instructed data from a main storage unit (not shown), and stores the data in an MIDQ 9104 (move-in). The data held in the MIDQ 9104 is written into a data memory 9106, and after writing, output to the core 9101 through a line LO, a selector 9107, a selector 9108, and a data bus 9109. For that reason, the read request for reading the data from the data memory 9106 is not required after move-in, and the latency when the cache miss occurs can be reduced.

Also, for the purpose of eliminating an external pin neck of a processor chip, and enlarging the throughput of an external memory, attention has paid to a 3D stacked technology using a through silicon via (TSV) or reactance coupling. This technology makes it possible to three-dimensionally couple the processor chip and the external chip, to thereby remarkably enlarge a bus bit width as compared with a related art, and increase the number of channels.

It is conceivable that if transfer of a high bit width can be conducted with the use of the above 3D stacked technology, transfer of data with respect to the external memory can be conducted with substantially the same throughput as that of the on-chip interconnect network used for coupling between the first level cache and the second level cache. The external memory is frequently configured by a DRAM from the viewpoints of the degree of integration and the costs.

An example of the 3D stacked configuration is disclosed in Japanese Unexamined Patent Publication No. 2009-157775. Japanese Unexamined Patent Publication No. 2009-157775 discloses a technique in which when the processor is configured by a plurality of LSI (large scale integration), the processor different in the capacity of the cache memory is easily configured while simplifying the circuit configuration.

Also, another example of the 3D stacked configuration is disclosed in Japanese Unexamined Patent Publication No. 2010-250511. FIG. 26 is a block diagram illustrating a configuration of a hardware architecture disclosed in Japanese Unexamined Patent Publication No. 2010-250511. The hardware architecture disclosed in Japanese Unexamined Patent Publication No. 2010-250511 is configured by a 3D stacked semiconductor integrated circuit in which an upper die 925 is stacked on a lower die 923. The lower die 923 is a one-chip SoC having a processor 921 and an SRAM (static random access memory) 922. The upper die 925 includes a DRAM (dynamic random access memory) 924. The processor 921 can selectively realize a tag mode and a cache mode.

An object of Japanese Unexamined Patent Publication No. 2010-250511 is to realize electric power saving while conducting the effective utilization of the memory in conformity to the characteristic of an execution status (execution application) of the processor 921. The cache mode is selected in a statue where an application small in a load is executed with respect to the capacity of the cache memory. In this case, a power supply of the stacked DRAM 924 is turned off to save the electric power. The L2 cache for the processor 921 is assumed by the SRAM 922, and operates as the small and fast L2 cache.

On the other hand, the tag mode is selected in a status where an application large in the load is executed with respect to the capacity of the cache memory. This is because it is desirable that the L2 cache has a large capacity. In this case, a power supply of the DRAM 924 turns on, and the DRAM 924 is used as a data array of the L2 cache. In the L2 cache configuration, because the data array of the cache has the large capacity, the number of entry of the cache is increased. Hence, the requested amount of capacity of the tag memory in the cache is also increased. Under the circumstances, in the case of the tag mode, the SRAM 922 is used as the cache tag memory. That is, the SRAM 922 selectively uses two kinds of functions including the cache data memory and the cache tag memory depending on the situation.

### SUMMARY

Now, a configuration of a general memory control device will be described, and a problem to be solved by the present invention will be described. FIG. 27 is a block diagram illustrating a configuration of a memory control device 93 in the related art. The memory control device 93 includes a processor core 931, an L1 cache 932, an L2 cache 933, an L2 HIT/MIS determination unit 9341, a response data selector 9342, an SDRAM controller 935, and an SDRAM 936. The memory control device 93 conducts an access control on a hierarchical memory. In this example, the hierarchical memory is realized by the L1 cache 932 of the highest level hierarchy, the L2 cache 933 of the second highest level hierarchy, and the SDRAM 936 of the lowest level hierarchy.

The processor core 931 makes an access request for reading or writing data to the hierarchical memory. In the following description, it is assumed that the access request is made for reading data. First, when the access request is made, the processor core 931 makes a cache hit determination in the L1 cache 932. If the determination is a cache hit, the processor core 931 reads a data string stored in the L1 cache 932, and processes the data string as response data to the access request. In this situation, the L2 cache 933 and the SDRAM 936 are not accessed. On the other hand, if the hit determination of the L1 cache 932 is a cache miss, the processor 931 makes an access request x1 to the L2 HIT/MIS determination unit 9341.

The L2 HIT/MIS determination unit 9341 makes the hit determination of the cache in the L2 cache 933 in response to the access request x1. More specifically, the L2 HIT/MIS determination unit 9341 checks an address included in the access request x1 against a tag 9331, determines whether the address is identical with the tag 9331, or not. If identical, the determination is the cache hit. If the determination is the cache hit, the L2 HIT/MIS determination unit 9341 gives a select instruction x4 for selecting an output from the L2 cache 933 to the response data selector 9342. Also, the L2 HIT/MIS determination unit 9341 reads the data string corresponding to the hit tag 9331 from a data array 9332, and outputs the read data string to the response data selector 9342. Then, the response data selector 9342 outputs the data string output from the L2 cache 933 to the processor core 931 as response data x5 to the access request x1. In this situation, the SDRAM 936 is not accessed. On the other hand, if the hit determination in the L2 HIT/MIS determination unit 9341 is the cache miss, the L2 HIT/MIS determination unit 9341 gives the select instruction x4 for selecting an output from the SDRAM controller 935 to the response data selector 9342. Also, the L2 HIT/MIS determination unit 9341 makes an access request x6 to the SDRAM controller 935.

The SDRAM controller 935 controls an access to the SDRAM 936 in response to the access request x6, and responds to the response data selector 9342. The SDRAM controller 935 includes a sequencer 9351, a ROW address generation unit 9352, a COL (column) address generation unit 9353, and a synchronization buffer 9354. The sequencer 9351 makes a RowOpen request to the SDRAM 936 through the ROW address generation unit 9352 in response to the access request x6. Subsequently, the sequencer 9351 makes a ColRead request through the COL address generation unit 9353. Then, a synchronizing buffer 9354 stores the data string read from the SDRAM 936 therein, and outputs the data string to the response data selector 9342. Then, the response data selector 9342 outputs the data string output from the SDRAM controller 935 to the processor core 931 as the response data x5 to the access request x1.

In this example, if the capacity of the L2 cache 933 is not sufficient, the hit ratio of the L2 cache is not increased, thereby making it difficult to obtain the latency reduction effect. However, in the embedded system where the costs and the power consumption limitation are hard, it is difficult to quite increase the capacity. For example, in order to reduce the capacity of the L2 cache 933, it is conceivable to reduce the number of data strings of the tag 9331 and the data array 9332 in the memory control device 93. However, when the capacity of the L2 cache 933 is merely reduced, the hit determination ratio in the L2 cache 933 is lessened, and the number of accesses to the SDRAM 936 is relatively increased. Because a response speed of the SDRAM 936 is lower than that of the L2 cache 933, an average latency as the entire memory control device 93 is increased.

On the other hand, in the future, it can be expected that an I/O of a multi-bit width is realized particularly by development of the 3D stacked technique to improve the throughput of the external memory. For example, in a wide I/O memory that has been increasingly standardized in the JEDEC (Joint Electron Device Engineering Council), an SDRAM (synchronous DRAM) of 128 bits is integrated into one die for four channels to realize the throughput of 12.8 GB/s. Accordingly, even in the case where an internal bus is of a 64 bit width, or where the internal bus is of a 128 bit width, if a plurality of channels is coupled to the same bus, a throughput equal to or higher than an internal bus speed can be expected. For that reason, even if the capacity of the L2 cache 933 is merely reduced, and the number of accesses to the SDRAM 936 is relatively increased as described above, it is conceivable that the throughput can be maintained.

However, even if an external memory mounted on another die different from that of the processor core is used, it takes a given time to read or write data from the memory cell since a read/write command is issued to the external memory. This is because, for example, if the external memory is the SDRAM 936, the SDRAM controller 935 can read a desired data string for the first time, by making the ColRead request after making the RowOpen request upon receiving the access request x6, and starting the SDRAM 936 from the viewpoints of the structure and the control specification. This makes it difficult to remarkably reduce the latency of the memory access, and in order to reduce the latency, there is a need to still provide the second level cache of the large capacity. That is, there arises such a problem that it is difficult to reduce the capacity of the second level cache while maintaining the reduction of the latency.

Japanese Unexamined Patent Publication No. 2009-288977 discloses a technique for reducing the latency if the cache miss occurs, but not reducing the capacity of the L2 cache memory. Also, Japanese Unexamined Patent Publication No. 2009-157775 discloses a technique for dispersing the L2 cache of the same hierarchy on a plurality of LSIs, but not reducing the capacity of the L2 cache memory.

Also, in the tag mode of Japanese Unexamined Patent Publication No. 2010-250511, the DRAM 924 is subsequently always accessed regardless of the result of the hit/miss determination of the tag for the SRAM 922. In the tag mode, it is possible to read large volumes of data from the 3D stacked DRAM 924 in a lump. However, in general, in the external memory device including the DRAM, a delay of several cycles occurs since a command for starting the access is issued from that configuration until first data is output, from the structural viewpoint. Accordingly, when the tag mode is used in the 3D stacked DRAM, the latency of the L2 cache in the cache mode is not affected. On the other hand, in the cache mode, the hit ratio of the L2 cache is lower than that of the tag mode. For that reason, even in Japanese Unexamined Patent Publication No. 2010-250511, it cannot be realized to reduce the capacity of the second level cache while maintaining the reduction of the latency.

According to a first aspect of the present invention, there is provided a memory control device, including: a first memory that is a cache memory of a given hierarchy; a second memory that is a cache memory of a lower level hierarchy than that of at least the first memory; a third memory that is a lower level hierarchy than that of at least the second memory, and longer in delay time since start-up until an actual data access than the first memory and the second memory; and a control unit that controls input and output of the first memory, the second memory, and the third memory, in which the second memory stores at least a part of data from each data string among a plurality of data strings with a given number of data as a unit, in which the third memory stores all of data within the plurality of data strings therein, in which if a cache miss occurs in the first memory, the control unit conducts hit determination of a cache in the second memory, and starts an access to the third memory, and in which if the result of the hit determination is a cache hit, the control unit reads the part of data falling under the cache hit from the second memory as leading data, reads data other than the part of data, of a data string to which the part of data belongs, from the third memory, and makes a response as subsequent data to the leading data.

According to a second aspect of the present invention, there is provided a memory control method in a memory control device, including: a first memory that is a cache memory of a given hierarchy; a second memory that is a cache memory of lower level hierarchy than that of at least the first memory; and a third memory that is a lower level hierarchy than that of at least the second memory, longer in delay time since start-up until an actual data access than the first memory and the second memory, and stores all of data within the plurality of data strings therein; the method including: if a cache miss occurs in the first memory, conducting hit determination of a cache in the second memory; starting an access to the third memory together with the hit determination; and if the result of the hit determination is a cache hit, reading the part of data falling under the cache hit from the second memory as leading data, reading data other than the part of data, of data string to which the part of data belongs, from the third memory, and making a response as subsequent data to the leading data.

According to a third aspect of the present invention, there is provided an information processing apparatus, including: a processor core; a first memory that is a cache memory of a given hierarchy; a second memory that is a cache memory of a lower level hierarchy than that of at least the first memory; a third memory that is a lower level hierarchy than that of at least the second memory, and longer in delay time since start-up until an actual data access than the first memory and the second memory; and a control unit that controls input and output of the first memory, the second memory, and the third memory, in which the second memory stores at least a part of data from each data string among a plurality of data strings with a given number of data as a unit, in which the third memory stores all of data within the plurality of data strings therein, in which if a cache miss occurs in the first memory, the control unit conducts hit determination of a cache in the second memory, and starts an access to the third memory, and in which if the result of the hit determination is a cache hit, the control unit reads the part of data falling under the cache hit from the second memory as leading data, reads data other than the part of data, of a data string to which the part of data belongs, from the third memory, and makes a response as subsequent data of the leading data.

According to a fourth aspect of the present invention, there is provided a memory control device, including: a first cache memory; a second cache memory that is a lower level hierarchy of at least the first cache memory; and an external memory that is a lower level hierarchy of at least the first cache memory, in which if a hit determination result of a cache in the second cache memory is a cache hit, the second cache memory and the external memory are memories of the same hierarchy, and in which the hit determination result is a cache miss, the external memory is a lower level hierarchy of the second cache memory.

According to a fifth aspect of the present invention, there is provided a memory control device having three or more memory hierarchies, in which if a cache miss occurs in a cache memory of a high level hierarchy, an access request is made to memories of a plurality of hierarchies which are lower level hierarchies than the hierarchy of the cache memory at the same time, and in which response data is responsive to the access request in the order of data response.

According to the first to third aspects of the present invention, if the cache hit occurs in the second memory, a part of data within the second memory is set as leading data, and the remaining data within the same data string within the third memory is set as subsequent data. As a result, an integrity of the response data can be taken. In this case, the second memory and the third memory are different in response speed from each other. For that reason, the part of data from the second memory can make a response at high speed as in the related art, but the remaining data from the third memory has a, latency. Under the circumstances, an access to the third memory starts together with the hit determination of the second memory so that a delay of a response time of the third memory can be complemented by a time during which the part of data is read from the second memory. As a result, the same latency as that when making a response by only the second memory can be maintained by the use of the second memory and the third memory which are different in the response speed. In this case, the second memory has only to store a part of data in the data string where the cache hit occurs, that is, only data which configures a leading portion of data when making a response, at minimum. Hence, the amount of stored data can be reduced while maintaining the same cache hit ratio in the second memory as that in the related art. That is, the memory capacity of the second memory can be reduced.

Also, according to the fourth aspect of the present invention, the hierarchy of the external memory can be changed on the basis of the hit determination result. For that reason, in the case of the cache hit in the second cache memory, a response can be made with the use of data from the external memory of the same hierarchy. Hence, there is no need to store all of the data in the data string associated with the cache hit in the second cache memory, and the capacity of the second cache memory can be reduced.

Also, according to the fifth aspect of the present invention, in the case of the cache hit in the L2 cache memory, there is a response from the L2 cache memory, and thereafter a response from the external memory of the hierarchy lower than that of the L2 cache memory in the stated order. Under the circumstances, the data read from the L2 cache memory can be output preferentially, and the data read from the external memory can be output as the subsequent data, as response data. For that reason, if only the data high in priority which is first required is stored in the L2 cache memory, the capacity of the L2 cache memory can be reduced while maintaining the effects of the latency reduction by the L2 cache memory.

According to the present invention, there can be provided the memory control device, the control method, and the information processing apparatus for reducing the capacity of the second level cache while maintaining the reduction of the latency by the second level cache.

### BRIEF DESCRIPTION OF THE DRAWINGS

FIG. 1 is a block diagram illustrating a configuration of a memory control device according to a first embodiment of the present invention;

FIG. 2 is a flowchart illustrating a flow of data read processing according to the first embodiment of the present invention;

FIG. 3 is a flowchart illustrating a flow of L2 cache hit processing according to the first embodiment of the present invention;

FIG. 4 is a flowchart illustrating a flow of an L2 cache miss processing according to the first embodiment of the present invention;

FIG. 5 is a diagram illustrating the effects of the L2 cache hit according to the first embodiment of the present invention;

FIG. 6 is a diagram illustrating the effects of the L2 cache miss according to the first embodiment of the present invention;

FIG. 7 is a diagram illustrating the effects of the L2 cache hit (a case where a latency is long) according to the first embodiment of the present invention;

FIG. 8 is a diagram illustrating the effects of the L2 cache hit (a case where the latency is short) according to the first embodiment of the present invention;

FIG. 9 is a diagram illustrating the effects of the L2 cache hit (a case where a throughput is low) according to the first embodiment of the present invention;

FIG. 10 is a diagram illustrating a concept of a relationship of data stored in respective memory hierarchies according to the first embodiment of the present invention;

FIG. 11 is a diagram illustrating a concept of a relationship of data stored in an L1 cache and an L2 cache according to the first embodiment of the present invention;

FIG. 12 is a flowchart illustrating a flow of L2 cache hit processing according to a second embodiment of the present invention;

FIG. 13 is a flowchart illustrating a flow of L2 cache miss processing according to the second embodiment of the present invention;

FIG. 14 is a diagram illustrating the effects of the L2 cache hit according to the second embodiment of the present invention;

FIG. 15 is a block diagram illustrating a configuration of a memory control device according to a third embodiment of the present invention;

FIG. 16 is a flowchart illustrating a flow of data read processing according to the third embodiment of the present invention;

FIG. 17 is a flowchart illustrating a flow of L2 cache hit processing according to the third embodiment of the present invention;

FIG. 18 is a flowchart illustrating a flow of L2 cache miss processing according to the third embodiment of the present invention;

FIG. 19 is a diagram illustrating the effects of the L2 cache hit according to the third embodiment of the present invention;

FIG. 20 is a block diagram illustrating a configuration of a memory control device in a multiprocessor according to a fourth embodiment of the present invention;

FIG. 21 is a diagram illustrating the effects of the L2 cache hit according to the fourth embodiment of the present invention;

FIG. 22 is a block diagram illustrating a configuration of a memory control device according to a fifth embodiment of the present invention;

FIG. 23 is a block diagram illustrating a configuration of an information processing apparatus according to a sixth embodiment of the present invention;

FIG. 24 is a diagram illustrating an example of a basic structure of a hierarchical cache in a related art;

FIG. 25 is a block diagram illustrating a configuration of a cache memory control device in the related art;

FIG. 26 is a block diagram illustrating a configuration of a hardware and architecture in the related art;

FIG. 27 is a block diagram illustrating a configuration of a memory control device in the related art;

FIG. 28 is a diagram illustrating a concept of a relationship of data stored in the L1 cache and the L2 cache in the related art; and

FIG. 29 is a block diagram illustrating a configuration of the memory control device in the multiprocessor in the related art.

### DETAILED DESCRIPTION

Hereinafter, specific embodiments according to the present invention will be described in detail with reference to the accompanying drawings. In the respective drawings, the same elements are denoted by identical reference numerals or symbols, and for clarification of description, a repetitive description of the same elements will be omitted as occasion demands.

### First Embodiment of the Invention

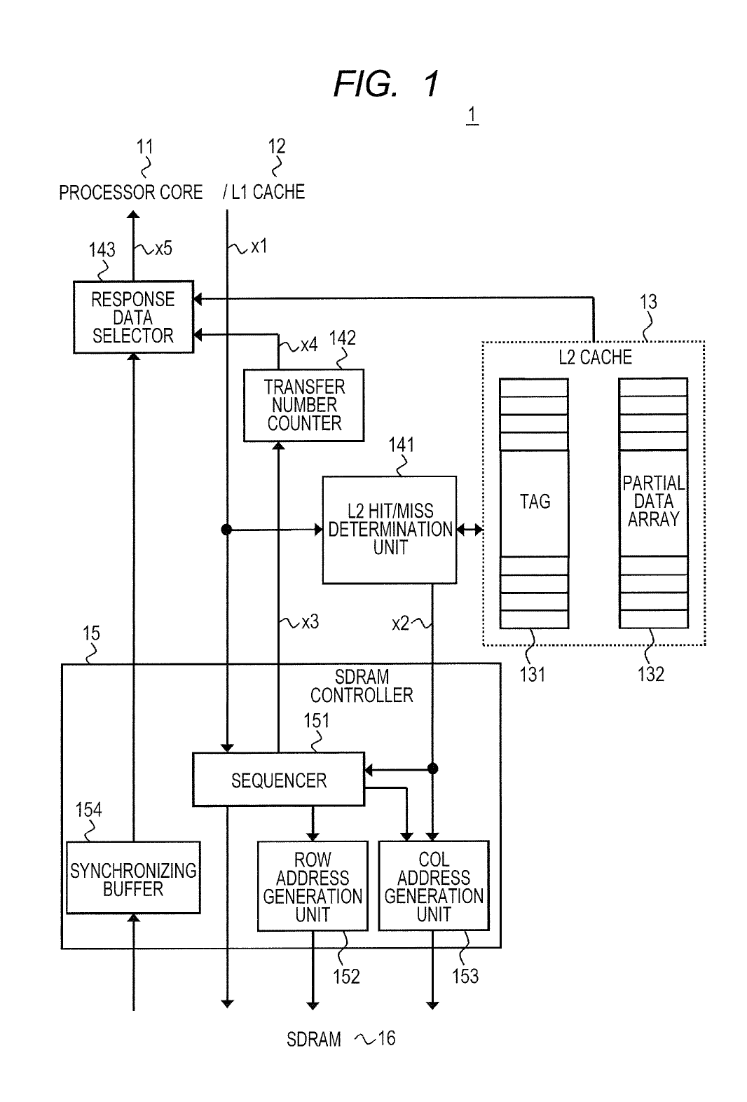

FIG. 1 is a block diagram illustrating a configuration of a memory control device 1 according to a first embodiment of the present invention. The memory control device 1 includes a processor core 11, an L1 cache 12, an L2 cache 13, an L2 HIT/MISS determination unit 141, a transfer number counter 142, a response data selector 143, an SDRAM controller 15, and an SDRAM 16. The memory control device 1 controls an access to a hierarchical memory. In this example, the hierarchical memory is realized by using the L1 cache 12 of a highest level hierarchy, the L2 cache 13 of a second highest level hierarchy, and the SDRAM 16 of a lowest level hierarchy.

The L1 cache 12 is a cache memory of the highest level hierarchy, which operates at the highest speed, and has the smallest capacity in the hierarchical memory. The L2 cache 13 is a cache memory of the lower level hierarchy than that of the L1 cache 12, which is lower in the speed and larger in the capacity than the L1 cache 12, but is higher in the speed and smaller in the capacity than the SDRAM 16. The L1 cache 12 and the L2 cache 13 can be each realized by, for example, an SRAM. The SDRAM 16 is a lower level hierarchy than that of the L2 cache 13, and low in the speed than the L2 cache 13, that is, low in the response speed and large in the capacity.

The L2 cache 13 stores a tag 131 and a partial data array. 132 therein. The partial data array 132 is a part of data in each data string among a plurality of data strings with a given number of data as a unit. Also, the partial data array 132 is a part of data in data strings other than data strings stored in at least the L1 cache 12. The tag 131 is address information corresponding to each data string in the partial data array 132. In general, the tag 131 includes tags within the L1 cache 12. Also, the L2 cache 13 may not be the second hierarchy of the memory, but may be, for example, an LLC (last level cache) immediately before the memory of the lowest level layer.

The SDRAM 16 stores all of data within the data strings to which at least the partial data array 132 belongs. In general, the SDRAM 16 stores data stored in the L1 cache 12 and the L2 cache 13 with the inclusion of the other data strings.

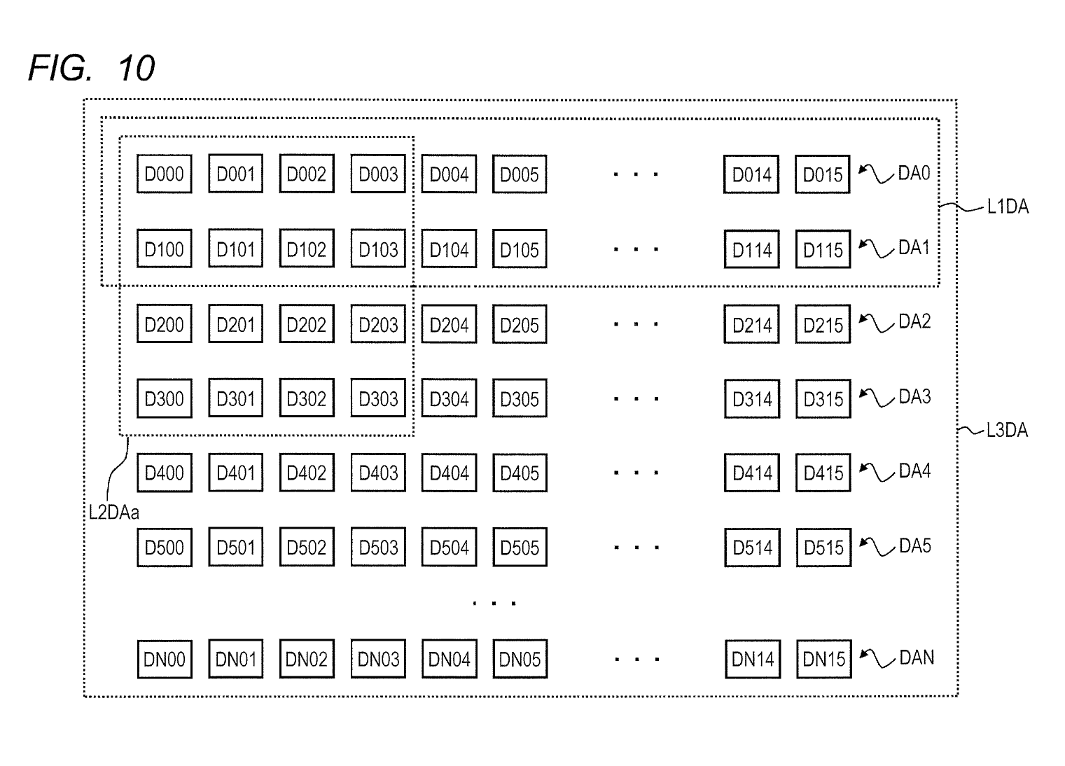

FIG. 10 is a diagram illustrating a concept of a relationship of data stored in the respective memory hierarchies according to the first embodiment of the present invention. First, it is assumed that a data set L3D is stored in the SDRAM 16. In this example, the data set L3D data strings DA0, DA1, DA2, . . . DAN. For example, data D000, D001, D002, . . . D014 belong to the data string DA0. The same is applied to the data strings DA1 to DAN.

Also, it is assumed that a data set L1D is stored in the L1 cache 12. The data set L1D includes the data strings DA0 and DA1. That is, the data set L1D is a subset of the data set L3D.

In this example, it is assumed that a data set L2D is stored in the L2 cache 13 according to the first embodiment of the present invention. The data set L2D includes data D000 to D003, data D100 to D103, data D200 to D203, and data D300 to D302. That is, the data set L2D is a part of data in each data string of the data strings DAD to DA3. The data set L2D may include at least a part of data D200 to D203 and D300 to D303 in the data strings DA2 and DA3 other than the data strings DAD and DA1 stored in the L1 cache 12.

Further, the L2 cache 13 may store a part of data in a large number of data strings as compared with a case in which all of data in each data string is stored. That is, the normal L2 cache stores all of each data string of the data strings DA0 to DA3, and can further store the data D400 to D403 and the data D500 to D503 within the limits thereof. As a result, the hit ratio in the L2 cache can be improved.

A description will be given again with reference to FIG. 1. The processor core 11 makes an access request for reading and writing data to the hierarchical memory. In particular, if a cache miss occurs in the L1 cache 12, the processor core 11 issues the access request x1 to the L2 HIT/MISS determination unit 141 and the SDRAM controller 15 at the same time. In the first embodiment, it is assumed that the access request is made for reading the data. Also, the L1 cache controller may be used instead of the processor core 11.

The L2 HIT/MISS determination unit 141 conducts the hit determination of the cache in the L2 cache 13 in response to the access request x1. More specifically, the L2 HIT/MISS determination unit 141 checks the address included in the access request x1 against the tag 131, determines whether the address is identical with the tag 131, or not. If identical, the L2 HIT/MISS determination unit 141 determines that the L2 cache 13 is the cache hit. If the determination is the cache hit, the L2 HIT/MISS determination unit 141 outputs determination result x2 with the inclusion of a fact that L2 is the cache hit, and an address to be read in the SDRAM 16 to a sequencer 151 and a COL address generation unit 153. In this situation, the address to be read is a value indicative of a position immediately after the number of data per data string of the partial data array 132. Also, the L2 HIT/MISS determination unit 141 reads partial data corresponding to the hit tag 131 in the partial data array 132, and outputs the read partial data to the response data selector 143. On the other hand, if the hit determination of the L2 HIT/MISS determination unit 141 is the cache miss, the L2 HIT/MISS determination unit 141 outputs the determination result x2 with the inclusion of a fact that L2 is the cache miss, and the address to be read in the SDRAM 16 to the sequencer 151 and the COL address generation unit 153. In this situation, the address to be read is a leading address per data string.

The transfer number counter 142 is a counter that measures the number of transfers of data read from the L2 cache 13 or the SDRAM 16. Also, the transfer number counter 142 gives the select instruction x4 to the response data selector 143 according to the number of transfers x3 from the sequencer 151. For example, a case in which the number of data of the partial data array 132 is “4” will be described. When the transfer number counter 142 is notified that L2 is the cache hit from the sequencer 151, the transfer number counter 142 gives the select instruction x4 so as to select data from the L2 cache 13 at the time where the number of transfers is “0”. Then, the transfer number counter 142 gives the select instruction x4 so as to select data from the SDRAM 16 at the time where the number of transfers is “4”. Also, when the transfer number counter 142 is notified that L2 is the cache miss from the sequencer 151, the transfer number counter 142 gives the select instruction x4 so as to select data from the SDRAM 16 at the time where the number of transfers is “0”.

The response data selector 143 is a selector circuit that selects data to be transferred from the L2 cache 13 or a synchronizing buffer 154 according to the select instruction x4, and outputs the selected data to the processor core 11 as the response data x5.

The SDRAM controller 15 controls an access to the SDRAM 16 in response to the access request x1, and responds to the response data selector 143. The SDRAM controller 15 includes the sequencer 151, a ROW address generation unit 152, the COL address generation unit 153, and the synchronizing buffer 154. Upon receiving the access request x1 from the processor core 11, the sequencer 151 issues a RowOpen request to the SDRAM 16 through the ROW address generation unit 152. In this example, the access request x1 is issued to the L2 HIT/MISS determination unit 141 and the sequencer 151 at the same time. Therefore, the RowOpen request is issued together with the hit determination in the L2 HIT/MISS determination unit 141. That is, an access to the SDRAM 16 starts during the hit determination. Then, the SDRAM 16 starts without waiting for the hit determination result, to advance preparations for reading the data.

Also, when receiving the determination result x2 from the L2 HIT/MISS determination unit 141, the sequencer 151 notifies the transfer number counter 142 of a fact that L2 is the cache hit or the cache miss, which is included in the determination result x2. At the same time, the sequencer 151 issues the ColRead request to the SDRAM 16 through the COL address generation unit 153. In this situation, because the SDRAM 16 has already been started, data is instantly read on the basis of the address designated by the ColRead request.

The ROW address generation unit 152 generates the RowOpen request to the SDRAM 16 according to an instruction from the sequencer 151, and outputs the generated RowOpen request. The COL address generation unit 153 reads the address to be read included in the determination result x2, and generates and outputs the ColRead request as a start address according to the instruction from the sequencer 151. The synchronizing buffer 154 stores the data string read from the SDRAM 16, and outputs the data string to the response data selector 143.

The L2 HIT/MISS determination unit 141, the transfer number counter 142, the response data selector 143, and the SDRAM controller 15 can be called “control unit” that controls input and output of the L2 cache 13 and the SDRAM 16.

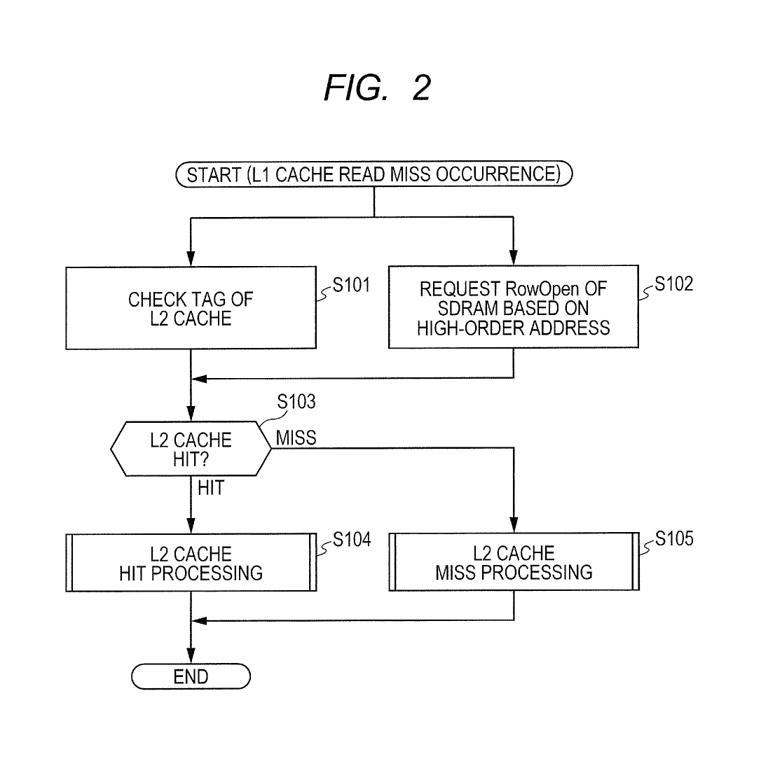

FIG. 2 is a flowchart illustrating a flow of data read processing according to the first embodiment of the present invention. In this example, a description will be given of a case in which a cache miss occurs in the L1 cache 12 in response to the read request. That is, a description will be given of a case in which the access request x1 is issued from the processor core 11 to the L2 HIT/MISS determination unit 141 and the sequencer 151.

First, the L2 HIT/MISS determination unit 141 checks the tag of the L2 cache 13 in response to the access request x1 (S101). In this situation, concurrently, the sequencer 151 issues the RowOpen request to the SDRAM 16 on the basis of an higher level address (S102). That is, the sequencer 151 uses the higher level address among the addresses for designating access targets included in the access request x1.

Then, the L2 HIT/MISS determination unit 141 determines whether an L2 cache hit occurs, or not (S103). If a cache hit occurs, the L2 HIT/MISS determination unit 141 conducts the L2 cache hit processing (S104). Also, if a cache miss occurs, the L2 HIT/MISS determination unit 141 conducts the L2 cache hit processing (S105).

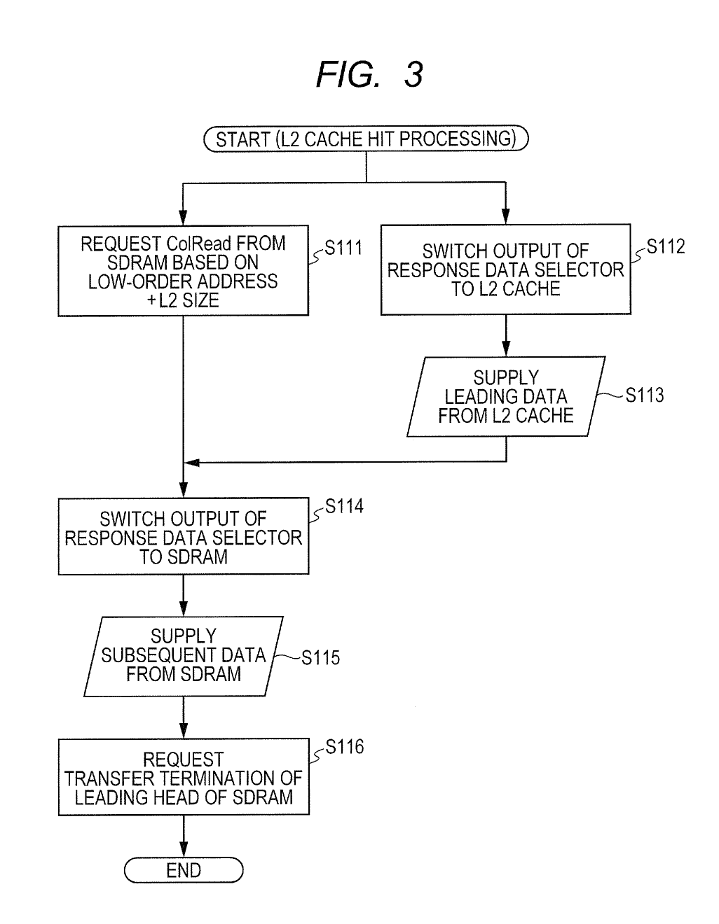

FIG. 3 is a flowchart illustrating a flow of the L2 cache hit processing according to the first embodiment of the present invention. First, the L2 HIT/MISS determination unit 141 notifies the sequencer 151 and the COL address generation unit 153 of a fact that L2 is the cache hit, and the determination result x2 that the address to be read in the SDRAM 16 is a value indicative of a position immediately after the number of data per data string of the partial data array 132. Then, the sequencer 151 issues the ColRead request to the SDRAM 16 through the COL address generation unit 153 on the basis of a lower level address+L2 size (S111). Concurrently, the transfer number counter 142 switches an output of the response data selector 143 to the L2 cache 13 through the L2 HIT/MISS determination unit 141 and the sequencer 151 (S112). Then, the L2 HIT/MISS determination unit 141 reads a part of data corresponding to an appropriate tag from the partial data array 132, and outputs the read data to the response data selector 143. The response data selector 143 supplies the data read from the L2 cache 13 to the processor core 11 as leading data (S113). That is, the response data selector 143 outputs the leading data of the response data x5 to the processor core 11.

Thereafter, when the number of transfers reaches “4”, the transfer number counter 142 switches the output of the response data selector 143 to the SDRAM 16 (S114). Then, subsequent data is supplied from the SDRAM 16 (S115). That is, data of the cache hit data strings other than the partial data array 132 is read from the SDRAM 16 as appropriate data on the basis of the ColRead request in Step S111, and stored in the synchronizing buffer 154. Then, the synchronizing buffer 154 outputs the read data to the response data selector 143. Thereafter, the response data selector 143 outputs the data to the processor core 11 as the subsequent data of the response data x5.

Finally, the sequencer 151 can issue a transfer termination request of the leading data to the SDRAM 16 (S116). After D15 is output from the SDRAM 16, wrap processing is conducted, and D0-D3 is sequentially output. For that reason, data overlapping with data of the partial data array 132 can be prevented from being wrap-read from the SDRAM 16. This is an option that can wrap-read the data as it is, and discard the data.

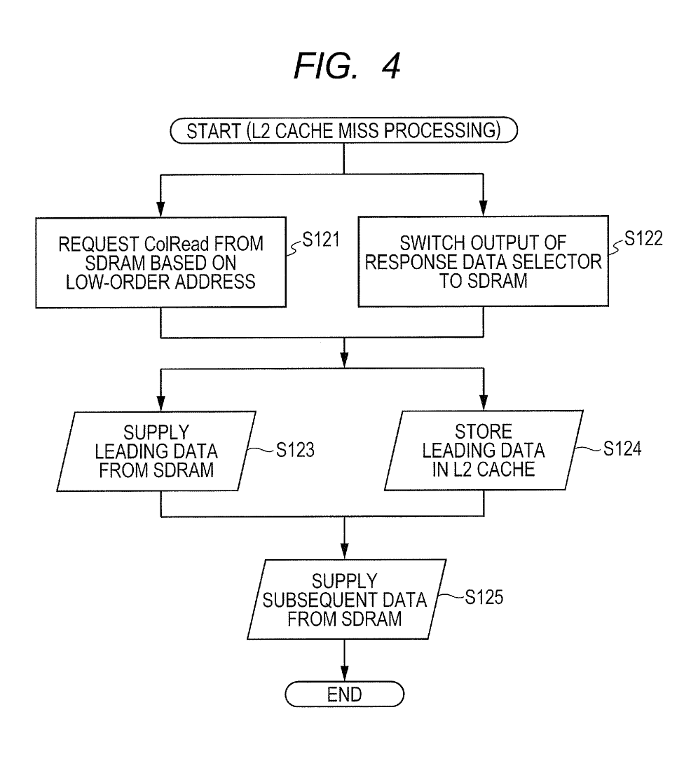

FIG. 4 is a flowchart illustrating a flow of the L2 cache miss processing according to the first embodiment of the present invention. First, the L2 HIT/MISS determination unit 141 notifies the sequencer 151 and the COL address generation unit 153 of a fact that L2 is the cache miss, and the determination result x2 that the address to be read in the SDRAM 16 is a head of each data string. Then, the sequencer 151 issues the ColRead request to the SDRAM 16 through the COL address generation unit 153 on the basis of a lower level address (S121). Concurrently, the transfer number counter 142 switches the output of the response data selector 143 to the SDRAM 16 through the L2 HIT/MISS determination unit 141 and the sequencer 151 (S122).

Thereafter, the transfer number counter 142 supplies the leading data from the SDRAM 16 (S123). That is, the leading data in the data strings where a cache miss occurs is read as the appropriate data from the SDRAM 16 on the basis of the ColRead request in Step S121, and stored in the synchronizing buffer 154. Then, the synchronizing buffer 154 outputs the data to the response data selector 143. Thereafter, the response data selector 143 outputs the data to the processor core 11 as the leading data of the response data x5. Concurrently, the appropriate leading data is stored in the L2 cache (S124). Then, the subsequent data is supplied from the SDRAM 16 (S125).

Thus, data highest in access frequency is stored in the L1 cache of the IP core such as the CPU on the data string basis. Then, the L2 cache functions as a cache used for hiding the latency. The L2 cache according to the first embodiment of the present invention stores only a part of the head of the data strings. Also, all of the data strings to meet the access request is stored in the external memory. Under the circumstances, the IP core can receive the supply of data from both of the L2 cache and the external memory when an L1 cache miss occurs.

According to the first embodiment of the present invention, as described above, when the processor core 11 first requests data because of the cache miss of the L1 cache, the L2 HIT/MISS determination unit 141 determines hit or miss of its own cache, and the external memory (for example, SDRAM 16) is activated.

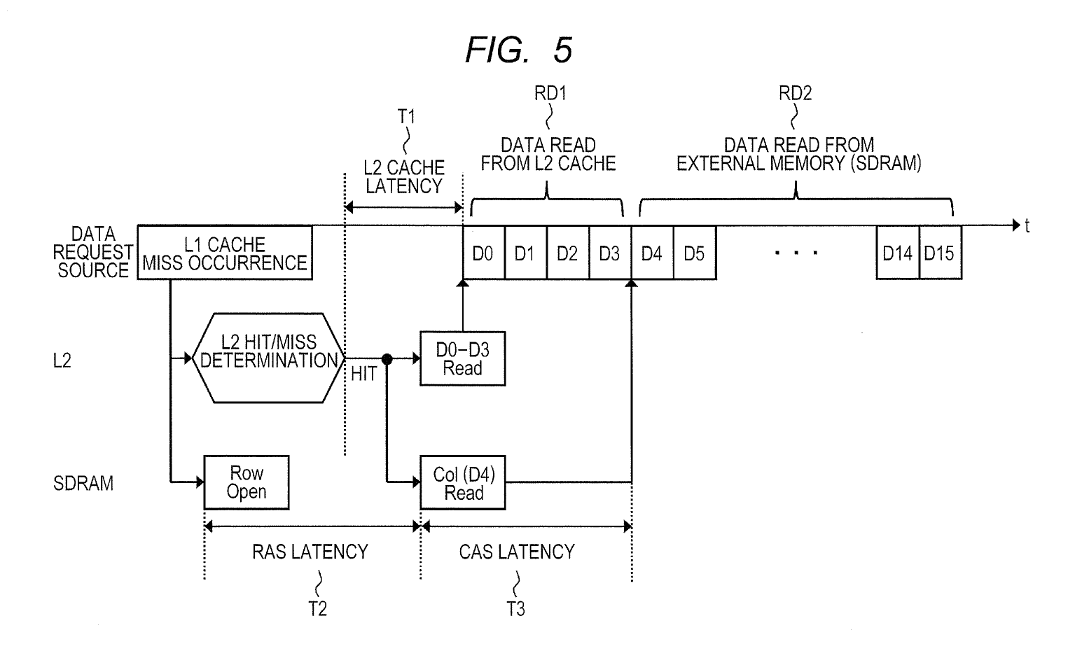

FIG. 5 is a diagram illustrating the effects of the L2 cache hit according to the first embodiment of the present invention. If an L2 cache hit occurs, a data group RD1 is supplied from the L2 cache after a latency T1 of the L2 cache. Also, the RowOpen request of the SDRAM starts after the L1 cache miss has occurred, and the ColRead request is made for D4 and subsequent data after the L2 HIT/MISS determination. For that reason, a data group RD2 can be supplied after (RAS latency T2+CAS latency T3) has been elapsed.

For that reason, the data group RD1 is data for several cycles corresponding to the latency of the external memory, as illustrated in FIG. 5, after the data group RD1 has been supplied from the L2 cache, the data group RD2 is sequentially supplied from the SDRAM. In other words, it is desirable that the data set L2D illustrated in FIG. 10 has the amount of data continuously read from the L2 cache 13 since an access to the SDRAM 16 starts until first data is read. As a result, the timing of the latency is matched, and a response speed when an L2 hit occurs can be maintained.

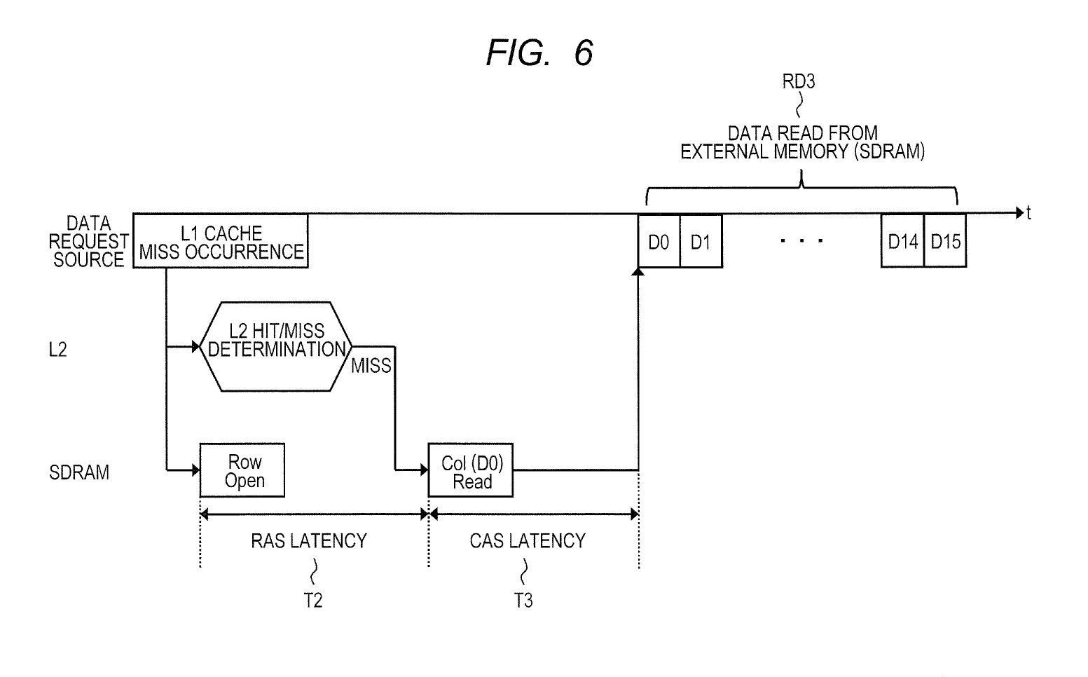

FIG. 6 is a diagram illustrating the effects of the L2 cache miss according to the first embodiment of the present invention. If an L2 cache miss occurs, a data group RD3 can be supplied from the SDRAM 16 after (RAS latency T2+CAS latency T3) has been elapsed. This is because the start of the external DRAM starts regardless of the hit/miss of the L2 cache. In the related art, if a hit occurs in the L2 cache, the start of the DRAM is wasted. Therefore, in a system emphasizing electric power saving, the DRAM normally starts after a miss has occurred in the L2 cache, and the latency when the miss occurs is longer than that in the case of FIG. 6. Hence, as compared with the related art that makes the RowOpen request after the L2 HIT/Miss determination, a response time can be reduced by the RAS latency T2 according to the first embodiment of the present invention.

Also, as described above, in the first embodiment of the present invention, it is assumed that the third memory is configured by the external memory, particularly the DRAM. In the case of the DRAM, the read access requires two steps including open of the Row address and issuance of the COL address and the command. In this example, in the open of the Row, the higher level address of the access address at which the L1 cache miss occurs is designated. That is, even in both of FIGS. 5 and 6, the higher level address is identical. Accordingly, when the Row address is open, there is no need to find the result of the hit/miss of the L2 cache. Thereafter, on the basis of the result of the hit/miss of the L2 cache, data transfer from D0 if a hit occurs, and data transfer from D4 if a miss occurs can be realized by issuance as the COL address.

In other words, preferably, the third memory is designed to read data on the basis of a first request for starting an access, and a second request for designating a data position to be read in the access within the data string. The control unit issues the first request to the third memory together with the hit determination in the second memory. If the result of the hit determination is the cache hit, the control unit designates data subsequent to the part of data in the data string falling under the cache hit as the data position, and issues the second request to the third memory. If the result of the hit determination is the cache miss, the control unit designates all of the data string falling under the cache miss as the data position, and issues the second request to the third memory. As a result, if the third memory is the DRAM, the RowOpen request is issued in advance, and the COL address is changed according to the L2 hit determination result, thereby changing the designation of the data position to be read to reduce the RAS latency time. In particular, the third memory can be applied to the DRAM based on the wide-I/O memory standards.

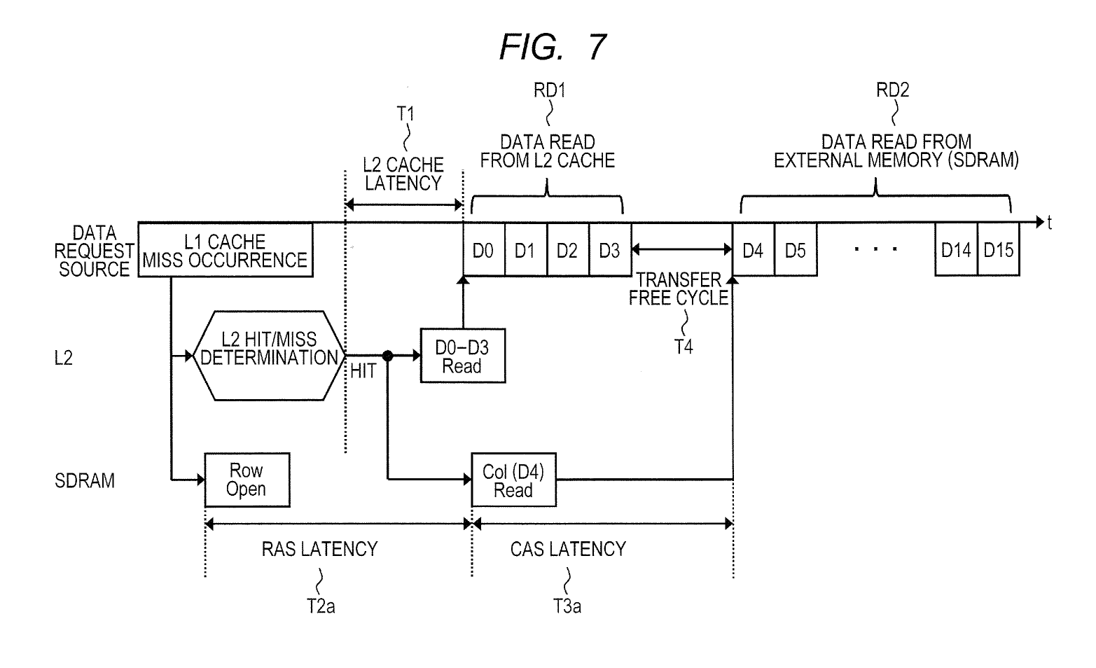

FIG. 7 is a diagram illustrating the effects of the L2 cache hit (a case where the latency is long) according to the first embodiment of the present invention. This example shows a case in which a CAS latency T3a in FIG. 7 is longer than the CAS latency T3. In this case, a transfer free cycle T4 occurs since the data group RD1 is supplied from the L2 cache until the data group RD2 is supplied from the SDRAM. Even in this case, if a mechanism allowing the IP core to process the earlier received data is provided, the sufficient effect can be produced. Even if such a mechanism is not provided, the latency reduction as long as at least the data group RD1 can be realized.

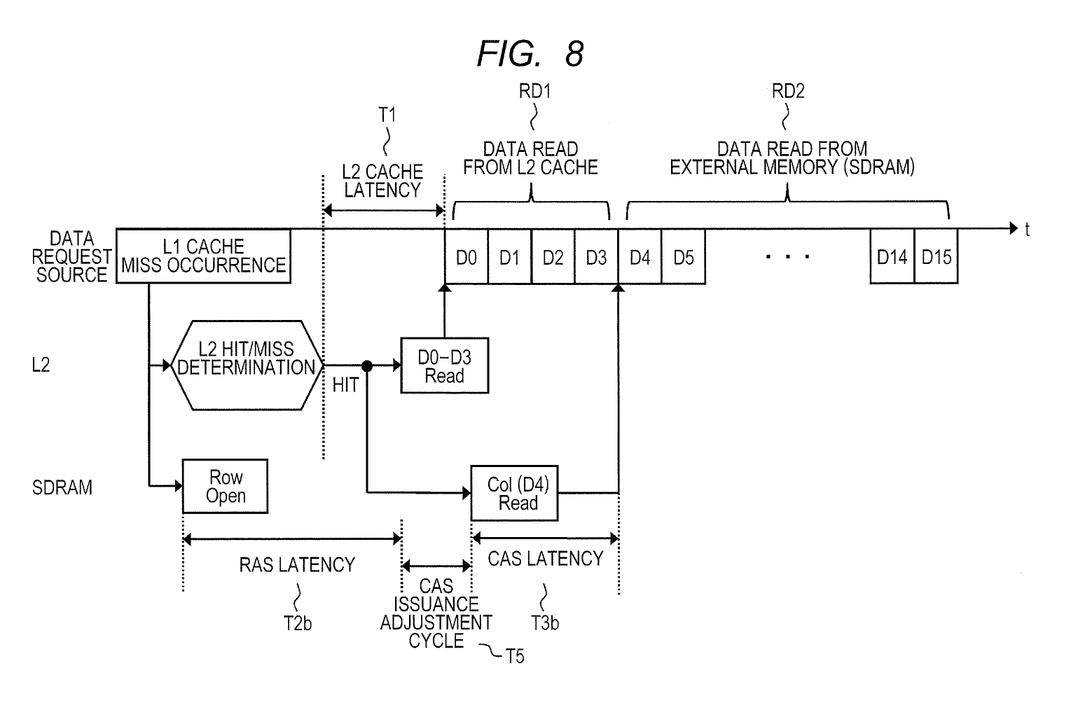

FIG. 8 is a diagram illustrating the effects of the L2 cache hit (a case where the latency is short) according to the first embodiment of the present invention. This example shows a case in which the CAS latency T3a in FIG. 7 is shorter than the CAS latency T3. In this case, an effective cost reduction method is to design hardware so as to reduce the partial data array size of the L2 cache. However, it is sufficiently assumed that a variety of SDRAM parameters exist. Under the circumstances, as illustrated in FIG. 8, a CAS issuance adjustment cycle T5 is inserted to delay CAS issuance so that data of D4 to be supplied from the SDRAM is output after data of D3 to be supplied from the L2 cache. With this configuration, the present invention can be applied without inserting an additional data buffer.

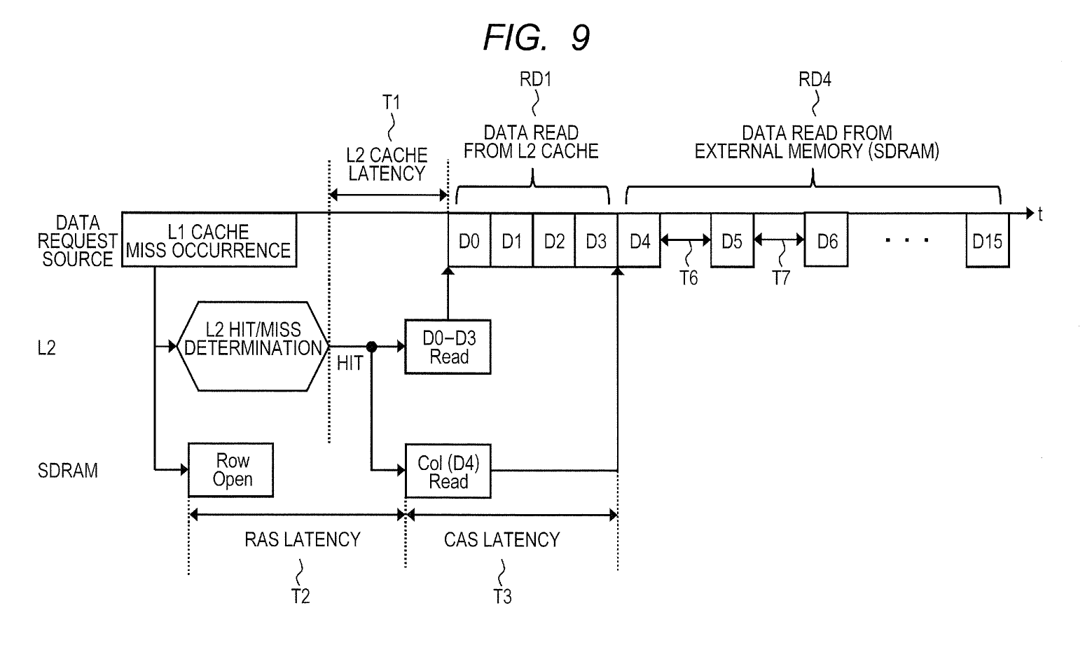

FIG. 9 is a diagram illustrating the effects of the L2 cache hit (a case where a throughput is low) according to the first embodiment of the present invention. This example shows a case in which the throughput of the SDRAM is lower than that of the L2 cache. In this situation, transfer free cycles T6 and T7 occur during the supply of a data group RD4. However, even in this case, the latency reduction as long as at least the data group RD1 can be realized as in FIG. 7.

Now, a description will be given of differences between the related art illustrated in FIG. 27 and the present invention illustrated in FIG. 1. In the related art, after the hit/miss determination has been completed by the L2 HIT/MIS determination unit 9341, if the cache miss occurs, a request for starting the access to the SDRAM is transmitted to the SDRAM controller 935. As a result, such an effect that the SDRAM 936 is not uselessly accessed can be expected. On the other hand, there arises such a problem that the access latency when the cache miss occurs is lengthened.

On the other hand, in the present invention, the hit/miss determination of the L2 cache 13 by the L2 HIT/MISS determination unit 141 and the access start request of the SDRAM 16 to the SDRAM controller 15 are conducted at the same time. This is because the cache according to the present invention aims at the effect of the latency reduction using the L2 cache. For that reason, the SDRAM 16 is also always accessed, but the access start request to the SDRAM 16 is not wasted even when the L2 cache hit occurs. This is because the partial data array 132 held by the L2 cache 13 is a part of the data strings held by the SDRAM 16.

Even if in the related art, the hit/miss determination of the L2 cache 933 and the access start request of the SDRAM 936 are simply conducted at the same time, when the L2 cache hit occurs, there is a need to cancel the access start request of the SDRAM 936. For that reason, in the related art, the wasted processing occurs, and the latency cannot be maintained.

Also, in the present invention, since the result of the L2 hit/miss determination affects the CAS access (occurrence of the COL address and the read command), it is designed to notify a CAS access generation logic of the hit/miss determination result of the L2 cache. If a hit occurs in the L2, a data acquisition start point of the SDRAM is obtained by adding a line size of the L2 cache to a request address from the L1, and the CAS address is issued. If a miss occurs in the L2, the request address from the L1 is issued as the CAS address as it is. Also, the response data selector times the amount of data transfer by the transfer number counter within the same access, and switches the data transfer from the L2 cache to the data transfer from the SDRAM at a time point when the data transfer by the amount corresponding to the L2 cache has been completed.

In other words, if the cache miss occurs in the first memory, the access to the third memory starts while the hit determination of the cache in the second memory is conducted. If the result of the hit determination is the cache hit, the part of data falling under the cache hit is read from the second memory as the leading data, and data of the data string to which the part of data belongs except for the part of data is read from the third memory, and serves as the subsequent data of the leading data.

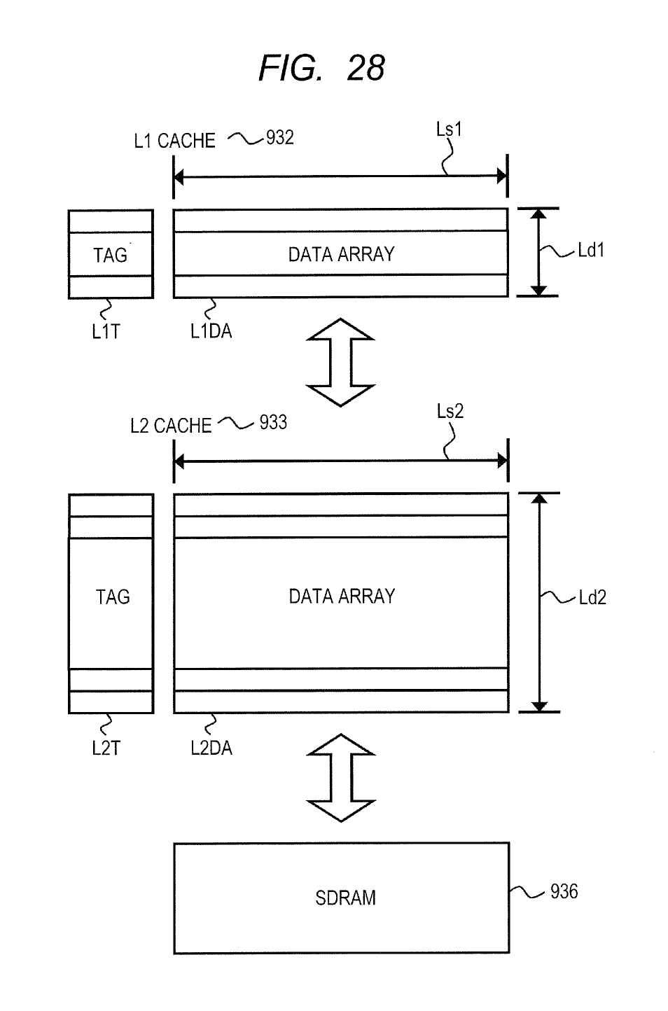

FIG. 28 is a diagram illustrating a concept of a relationship of data stored in the L1 cache and the L2 cache in the related art. A tag L1T and a data array L1DA are stored in the L1 cache 932. The tag L1T and the data array L1DA are the number of arrays Ld1. Also, the data array L1DA is a line size Ls1. Also, a tag L2T and a data array L2DA are stored in the L2 cache 933. The tag L2T and the data array L2DA are the number of arrays Ld2. Also, the data array L2DA is a line size Ls2. The data array L1DA is included in the data array L2DA, and the data array L2DA is included in the SDRAM 936.

If a hit occurs in the L2 cache 933, no access to the SDRAM 936 occurs. In order to obtain the effect of the L2 cache 933, there is a need to ensure the data array L2DA of a sufficient capacity as compared with the data array L1DA in the L2 cache 933. However, in the embedded system, the costs are largely difficult to realize.

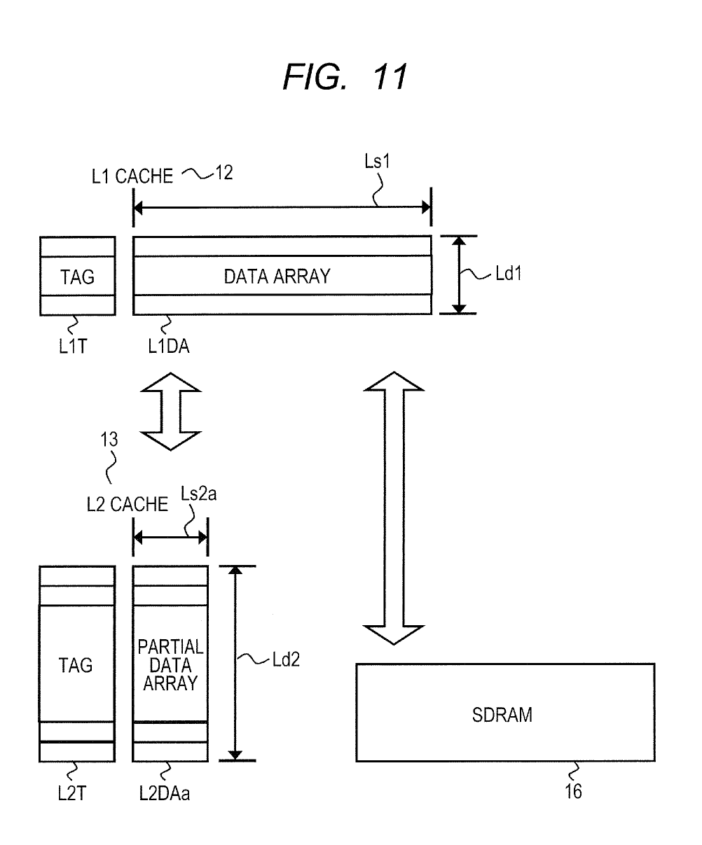

FIG. 11 is a diagram illustrating a concept of a relationship of data stored in the L1 cache and the L2 cache according to the first embodiment of the present invention. The L1 cache 12 has the same configuration as that of the L1 cache 932. If a cache miss occurs in the L1 cache 12, action is taken with the contents stored in the L2 cache 13 and the SDRAM 16.

The tag L2T and a partial data array L2DAa are stored in the L2 cache 13. The tag L2T and the partial data array L2DAa are the number of arrays. Ld2, which is equivalent to that in FIG. 28. On the other hand, the partial data array L2DAa is a line size Ls2a which is different from that in FIG. 28.

In this example, in FIG. 28, the line size Ls2 of the individual cache entries in the L2 cache 933 needs to be equal to or larger than the line size Ls1 of the L1 cache 932. On the other hand, in FIG. 11, the line size Ls2a of the L2 cache 13 can be made sufficiently smaller than the line size Ls1 of the L1 cache 12. With this configuration, the latency of the external memory can be effectively reduced, and the memory capacity that is problematic in the L2 cache can be remarkably reduced.

On the other hand, even when a hit occurs in the L2 cache 13, the SDRAM 16 is always accessed. However, as described in the background, it is conceivable that a reduction of the I/O power and an increase in the bandwidth due to the 3D stacked structure are effectively used, and the disadvantage caused by this configuration can be reduced by coupling the external memory using an external chip up to now.

The first embodiment of the present invention can be expressed as follows. That is, the first embodiment provides a memory control device which includes a first cache memory, a second cache memory that is a lower level hierarchy of at least the first memory, and an external memory that is a lower level hierarchy of at least the first memory, in which if the hit determination result of the cache in the second cache memory is the cache hit, the second cache memory and the external memory are configured by memories of the same hierarchy, and if the hit determination result of the cache in the second cache memory is the cache miss, the external memory is configured by the lower level hierarchy of the second cache memory. With this configuration, the hierarchy of the external memory can be changed on the basis of the hit determination result. For that reason, if the cache hit occurs in the second cache memory, action can be taken with the use of the data from the external memory of the same hierarchy. Hence, there is no need to store, in the second cache memory, all of data in the data strings falling under the cache hit, and the capacity of the second cache memory can be reduced.

Also, the first embodiment of the present invention can be expressed as follows. That is, the first embodiment provides a memory control device having three or more memory hierarchies, in which if the cache miss occurs in the cache memory of the higher level hierarchy, an access request is made to the memories of the plural hierarchies which are lower level hierarchies than the cache memory at the same time, and response data to the access request is obtained in the order of the data response. With this configuration, if the cache hit occurs in the L2 cache memory, a response from the L2 cache memory is obtained, and thereafter a response from the external memory of the hierarchy lower than that of the L2 cache memory is obtained, in order. Under the circumstances, the data read from the L2 cache memory can be output preferentially, and the data read from the external memory can be output as the subsequent data, as response data. For that reason, if only the data high in priority is stored in the L2 cache memory, the capacity of the L2 cache memory can be reduced.

### Second Embodiment of the Invention

In the above-mentioned first embodiment of the present invention, a description is given of the case in which when the L1 cache miss occurs, a missed line is read from the L2 cache or the external memory. On the other hand, in the case of write, that is, even if data of a specific cache line of the L1 cache mismatches the main memory, and the cache line is evicted from the L1 cache, a delay occurs in the external memory. As with read, in this case, because the COL address and the command are issued after the Row address is opened, a time during this operation becomes a delay time, and eviction of the cache line from the L1 cache is delayed.

Under the circumstances, in a second embodiment of the present invention, a description will be given of a case in which only a first portion of eviction from the L1 cache is loaded into the L2 cache. With this configuration, the latency of the DRAM is hidden. Since the DRAM can circulatingly write data for one page, data loaded into the L2 cache is sequentially written into the DRAM after data from the L1 cache has been written. Accordingly, in the present invention, data stored in the L2 cache is maintained in a state of always matching with the DRAM memory, and write-back by eviction of an entry of the L2 cache does not occur. Those processing makes it possible to hide the delay of the external memory even at the time of write-back of the L1 cache.

That is, a control unit according to the second embodiment of the present invention writes, in response to a request for writing a specific data string, a part of data in the specific data string into the second memory, and writes data in the specific data string other than the part of data into the third memory. After writing the data into the third memory, the control unit writes the part of data written into the second memory, into the third memory. With this configuration, write of the data into the third memory starts before write of the data into the second memory (for example, L2 cache) has been completed, and synchronization of the second memory and the third memory is quickened. The configuration of the memory control device according to the second embodiment of the present invention is identical with those in FIG. 1, and therefore, and an illustration and description of the configuration will be omitted.

An entire flow of data write processing according to the second embodiment of the present invention is identical with that in FIG. 2 described above, and therefore L2 cache hit processing and L2 cache miss processing will be described below.

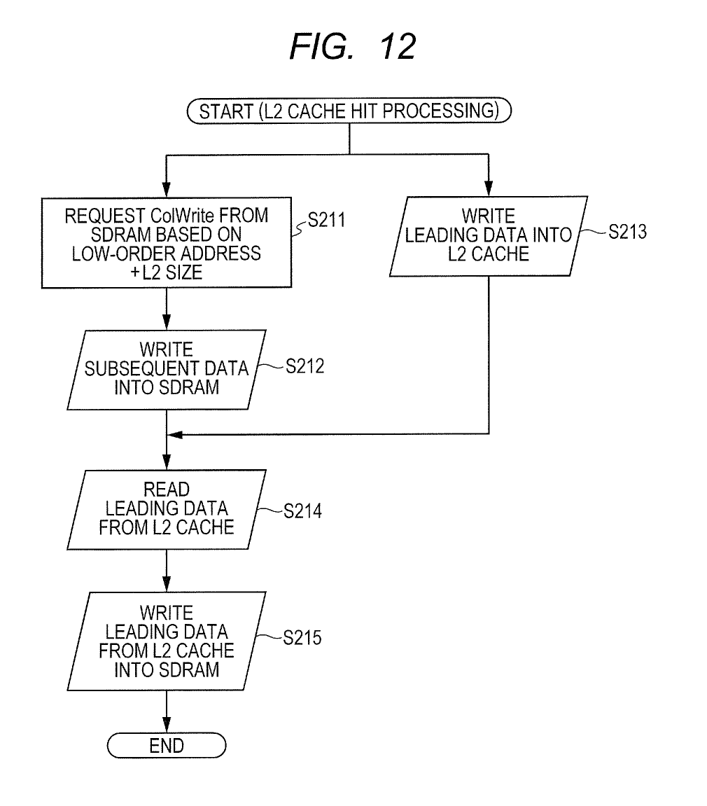

FIG. 12 is a flowchart illustrating a flow of the L2 cache hit processing according to the second embodiment of the present invention. First, the L2 HIT/MISS determination unit 141 notifies the sequencer 151 and the COL address generation unit 153 of a fact that L2 is the cache hit, and the determination result x2 that the address to be written in the SDRAM 16 is a value indicative of a position immediately after the number of data per data string of the partial data array 132. Then, the sequencer 151 issues a ColWrite request to the SDRAM 16 through the COL address generation unit 153 on the basis of a lower level address+L2 size (S211). Concurrently, the L2 HIT/MISS determination unit 141 writes leading data into the L2 cache 13 (S213). In this example, the number of data to be written is the number of data in the partial data array 132. Also, after Step S211, the sequencer 151 writes subsequent data into the SDRAM 16 through the COL address generation unit 153 (S212).

Thereafter, the L2 HIT/MISS determination unit 141 reads the leading data from the SDRAM 16 (S214). Then, the sequencer 151 writes the leading data from the L2 cache 13 into the SDRAM 16 (S215).

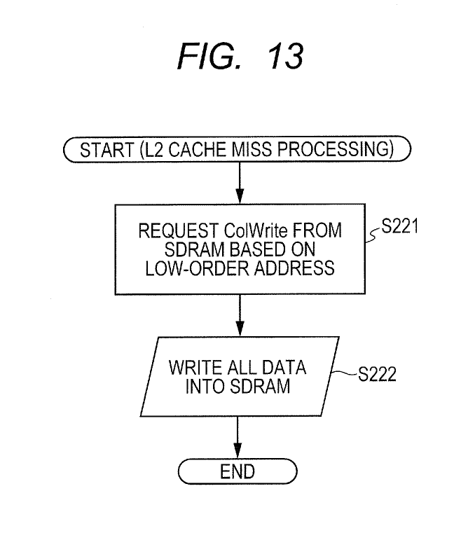

FIG. 13 is a flowchart illustrating a flow of the L2 cache miss processing according to the second embodiment of the present invention. First, the L2 HIT/MISS determination unit 141 notifies the sequencer 151 and the COL address generation unit 153 of a fact that L2 is the cache miss, and the determination result x2 that the address to be written in the SDRAM 16 is a head of each data string. Then, the sequencer 151 issues the ColWrite request to the SDRAM 16 through the COL address generation unit 153 on the basis of a lower level address (S221). Sequentially, the sequencer 151 writes all of the data into the SDRAM 16 (S222).

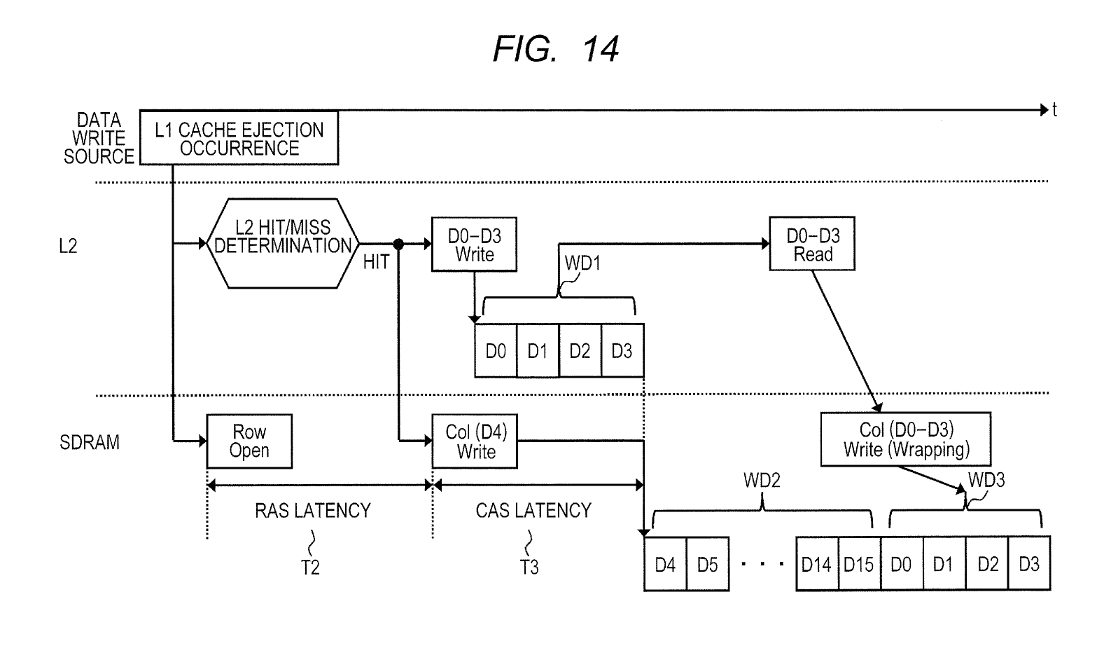

FIG. 14 is a diagram illustrating the effects of the L2 cache hit according to the second embodiment of the present invention. If an eviction occurs in the L1 cache, the processor core 11 first issues the access request x1 for writing data to the L2 HIT/MISS determination unit 141 and the sequencer 151. Then, if the L2 cache hit occurs, a data group WD1 is written into the L2 cache 13. On the other hand, concurrently, the RowOpen request and the ColWrite request from the D4 are issued to the SDRAM 16, and a data group WD2 is written after (RAS latency T2+CAS latency T3) has been elapsed. Then, the data group WD1 is read from the L2 cache 13 before the write of the data group WD2 is completed, and a data group WD3 is sequentially written after the write of the data group WD2, has been completed. In this example, the data group WD3 is the data group WD1 read from the L2 cache 13.

### Third Embodiment of the Invention

Some of general-purpose microprocessors which are one configuration of the IP core provide a critical word first transfer in which for the purpose of reducing the delay time in the cache miss, necessary data is first transferred, and processing is restarted upon arrival of the data, even if the cache miss is not completely eliminated. The above-mentioned L2 cache 13 is designed to cache a part of an L1 cache line. This case does not need to be limited to holding only the several cycles of the head. In the IP core, a pattern of data reference inducing the L1 cache miss frequently has reproducibility. Accordingly, the pattern of the data transfer by the critical word first transfer may be repeated in the same manner. Hence, a position of the data stored in an L2 cache 13a according to the third embodiment of the present invention is set to a part of data first transferred, to thereby obtain the effects of the latency reduction according to the present invention.

That is, the second memory further stores partial tag information indicative of a data position of the part of data within the data string. The control unit determines that the cache hit occurs if the partial tag information corresponds to the designated data position in the hit determination, in response to the access request including the designation of the specific data position to be output preferentially within the data string. If the result of the hit determination is the cache hit, the control unit reads the part of data corresponding to the partial tag information falling under the cache hit from the second memory as the leading data. As a result, the same effects can be obtained even in the critical word first transfer.

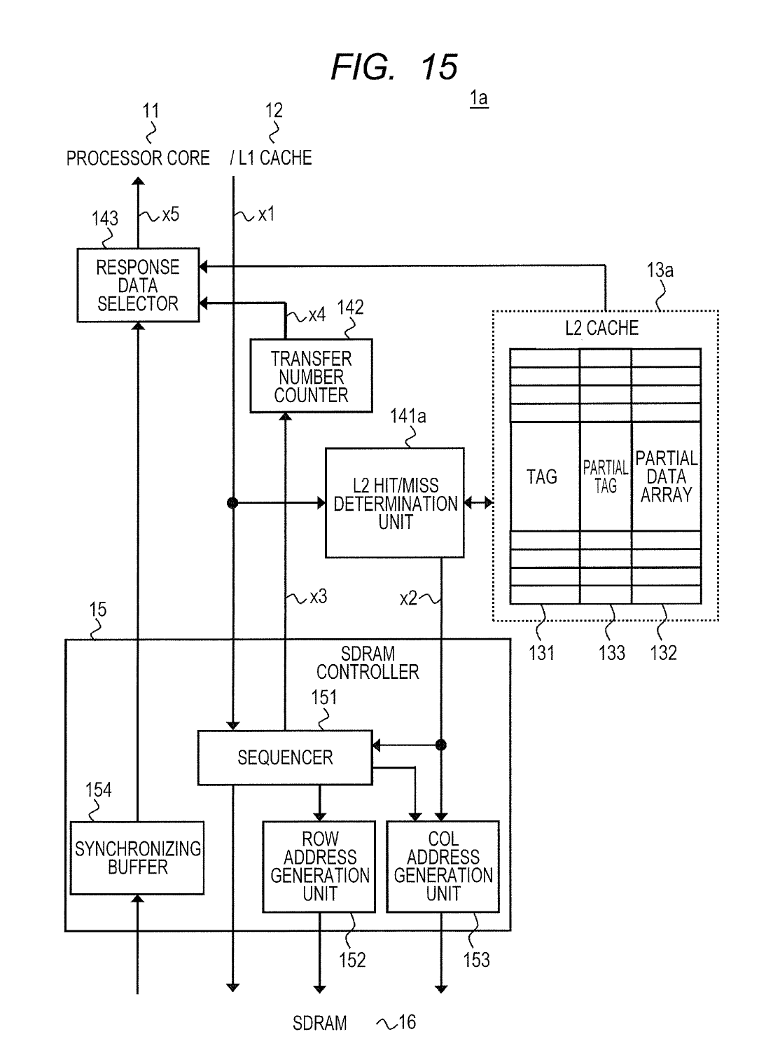

FIG. 15 is a block diagram illustrating a configuration of a memory control device 1a according to the third embodiment of the present invention. In the configuration of the memory control device 1a according to the third embodiment of the present invention, the same elements as those in FIG. 1 are denoted by identical symbols or references, and an illustration and description of the configuration will be omitted. The L2 cache 13a includes a partial tag 133 in addition to the L2 cache 13. The partial tag 133 indicates that the partial data array 132 stores data corresponding to any data string to meet the access request x1.

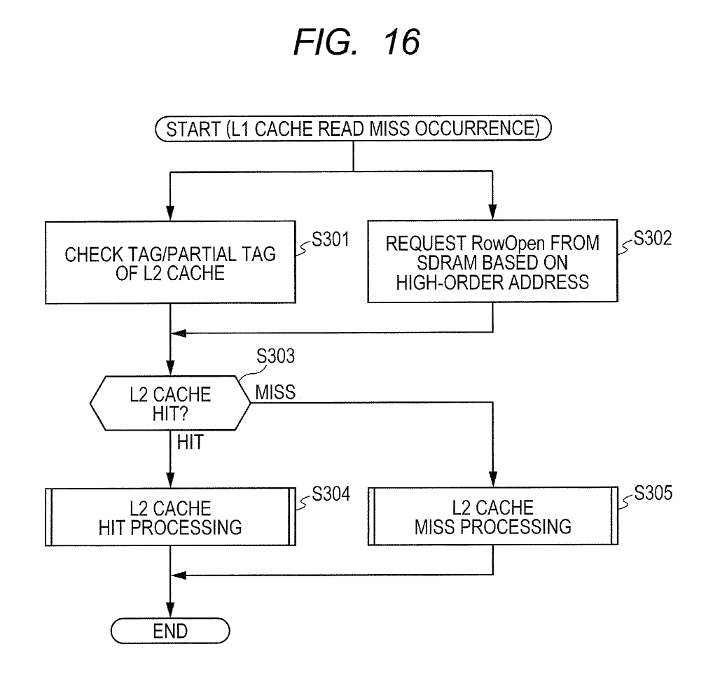

FIG. 16 is a flowchart illustrating a flow of data read processing according to the third embodiment of the present invention. In this example, a description will be given of a case in which the cash miss occurs in the L1 cache 12 in response to the read request. That is, a description will be given of a case in which the access request x1 is issued from the processor core 11 to the L2 HIT/MISS determination unit 141 and the sequencer 151.

First, an L2 HIT/MISS determination unit 141a checks the tag and the partial tag in the L2 cache 13a in response to the access request x1 (S301). In this situation, concurrently, the sequencer 151 issues the RowOpen request to the SDRAM 16 on the basis of the higher level address (S302).

Then, the L2 HIT/MISS determination unit 141a determines whether a hit occurs in the L2 cache, or not (S303). If the hit occurs therein, the L2 HIT/MISS determination unit 141a conducts L2 cache hit processing (S304). Also, if a miss occurs therein, the L2 HIT/MISS determination unit 141a conducts L2 cache miss processing (S305).

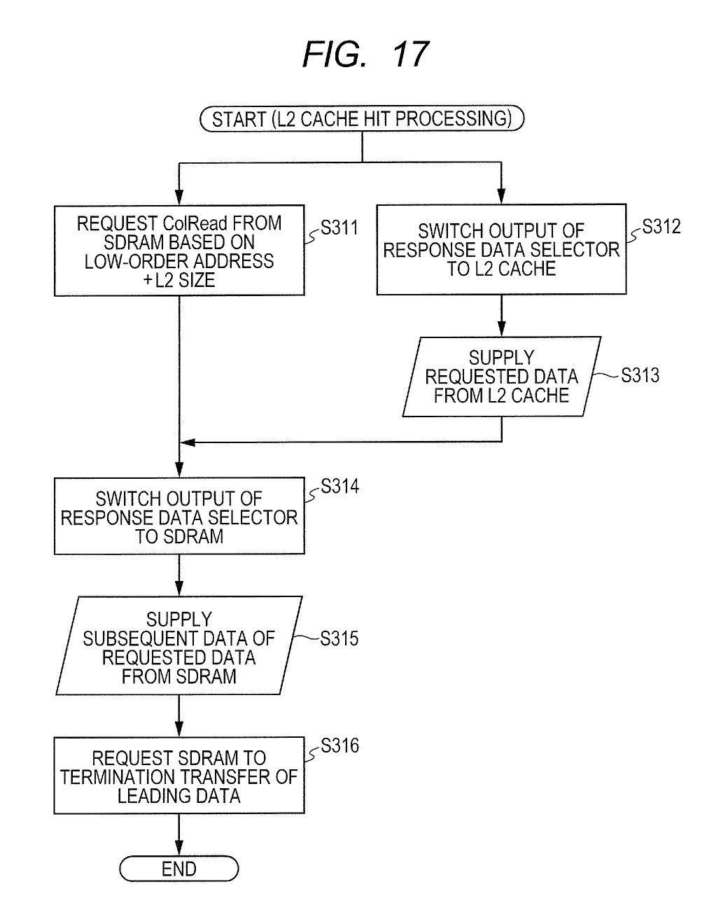

FIG. 17 is a flowchart illustrating a flow of the L2 cache hit processing according to the third embodiment of the present invention. First, the L2 HIT/MISS determination unit 141a notifies the sequencer 151 and the COL address generation unit 153 of a fact that L2 is the cache hit, and the determination result x2 that the address to be read in the SDRAM 16 is a value indicative of a position immediately after the number of data per data string of the partial data array 132. Then, the sequencer 151 issues the ColRead request to the SDRAM 16 through the COL address generation unit 153 on the basis of a lower level address+L2 size (S311). Concurrently, the transfer number counter 142 switches the output of the response data selector 143 to the L2 cache 13 through the L2 HIT/MISS determination unit 141a and the sequencer 151 (S312). Then, the L2 HIT/MISS determination unit 141a supplies a request data from the L2 cache 13a (S313). That is, the L2 HIT/MISS determination unit 141a reads a part of data corresponding to the appropriate partial tag 133 at the data position designated by the access request x1, and outputs the read data to the response data selector 143. The response data selector 143 outputs the leading data of the response data x5 to the processor core 11.

Thereafter, when the number of transfers reaches “4”, the transfer number counter 142 switches the output of the response data selector 143 to the SDRAM 16 (S314). Then, the transfer number counter 142 supplies the subsequent data of the request data from the SDRAM 16 (S315). Finally, the sequencer 151 makes a request for terminating transfer of the leading head to the SDRAM 16 (S316).

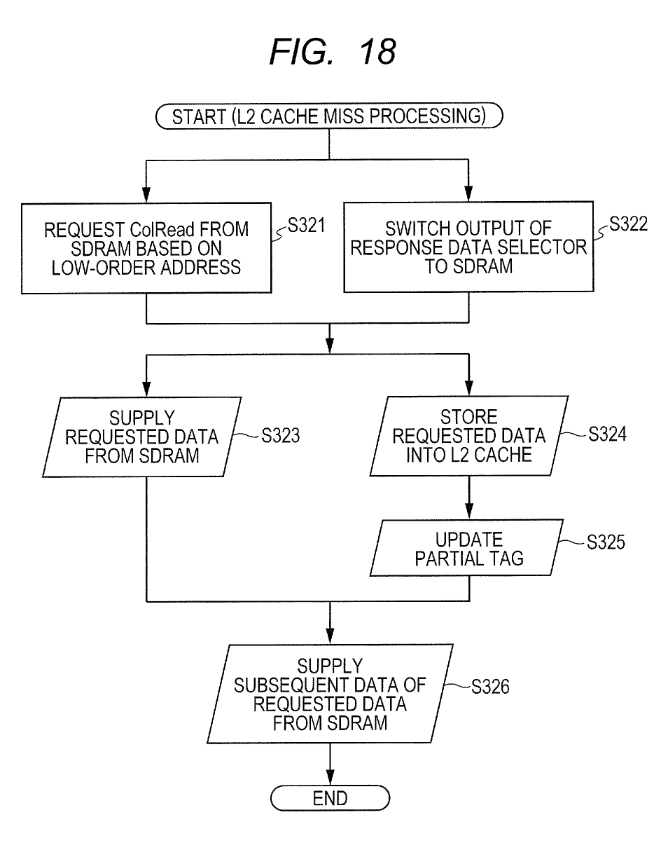

FIG. 18 is a flowchart illustrating a flow of the L2 cache miss processing according to the third embodiment of the present invention. First, the L2 HIT/MISS determination unit 141a notifies the sequencer 151 and the COL address generation unit 153 of a fact that L2 is the cache miss, and the determination result x2 that the address to be read in the SDRAM 16 is a head of each data string. Then, the sequencer 151 issues the ColRead request to the SDRAM 16 through the COL address generation unit 153 on the basis of a lower level address (S321). Concurrently, the transfer number counter 142 switches the output of the response data selector 143 to the SDRAM 16 through the L2 HIT/MISS determination unit 141a and the sequencer 151 (S322).

Thereafter, the L2 HIT/MISS determination unit 141a supplies the request data from the SDRAM 16 (S323). Concurrently, the L2 HIT/MISS determination unit 141a stores the request data in the L2 cache 13a (S324). Then, the L2 HIT/MISS determination unit 141a updates the partial tag 133 (S325). Thereafter, the L2 HIT/MISS determination unit 141a supplies the subsequent data of the request data from the SDRAM 16 (S326).

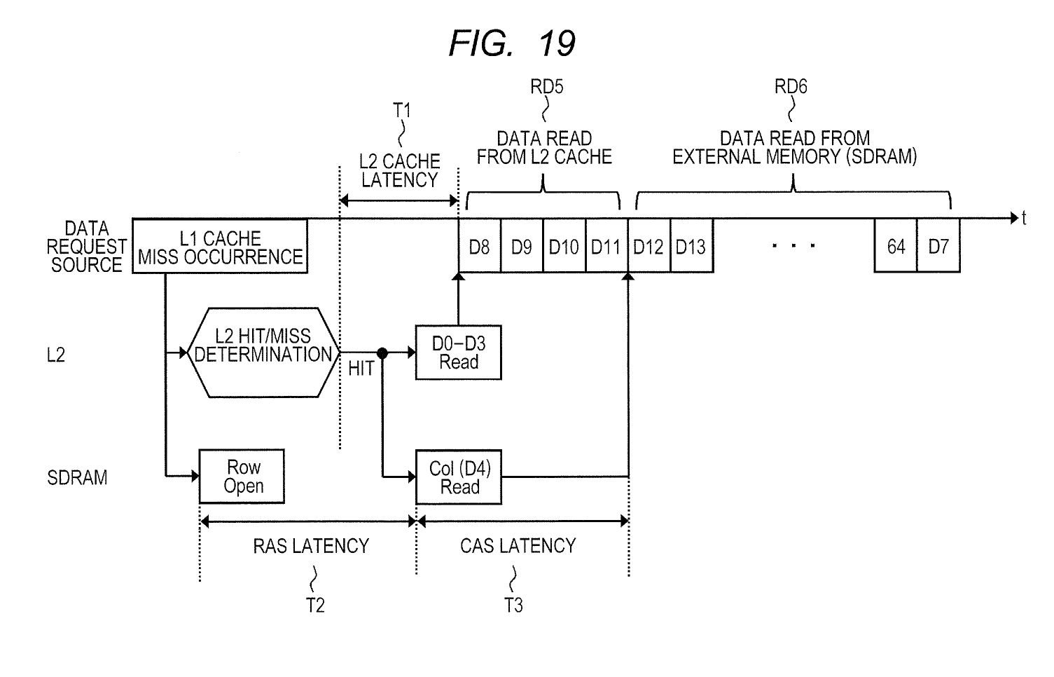

FIG. 19 is a diagram illustrating the effects of the L2 cache hit according to the third embodiment of the present invention. In this example, data D8 is data inducing a cache miss, that is, critical word. As soon as a data group RD5 including the data D8 arrives at the L1 cache, the IP core can restart the processing. If the partial data including the data D8 is stored in the L2 cache, the IP core executes the control to supply, after appropriate data has been supplied from the L2 cache, data other than that data is supplied from the external memory.

With the above configuration, the same advantages as those in the first embodiment of the present invention can be obtained. However, because it is assumed that the hit ratio of the L2 cache is slightly lessened, different partial data located in the same L1 cache entry can be also stored in a plurality of L2 cache entries, so as to deal with the start address of access having a low repetitive property.

### Fourth Embodiment of the Invention

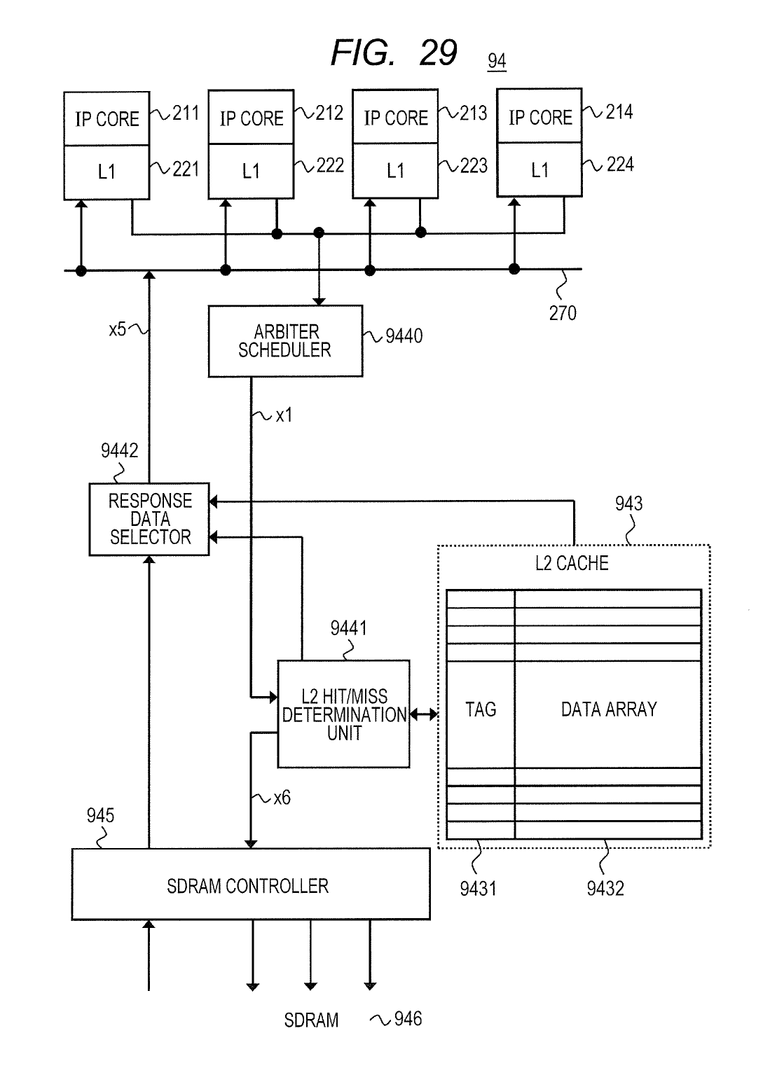

In a fourth embodiment of the present invention, a description will be given of a case in which an SDRAM control as a shared memory and a shared L2 cache are used in a multicore configuration. FIG. 29 is a block diagram illustrating a configuration of a memory control device 2 in the multiprocessor in the related art. A memory control device 94 includes IP cores 211 to 214, L1 caches 221 to 224, an L2 cache 943, an arbiter scheduler 9440, an L2 HIT/MISS determination unit 9441, a response data selector 9442, an SDRAM controller 25, and an SDRAM 26.

The IP cores 211 to 214 include the L1 caches 221 to 224, respectively, and each issues an access request to the arbiter scheduler 9440 if an L1 cache miss occurs. The L2 cache 943 stores a tag 9431 and a data array 9432 therein. The arbiter scheduler 9440 accepts a plurality of access requests, and conducts arbitration, and then issues the access request x1 to the L2 HIT/MISS determination unit 9441 one by one.

The L2 HIT/MISS determination unit 9441 conducts the hit determination of the cache in the L2 cache 933 in response to the access request x1. Thereafter, the same processing as that in FIG. 27 is conducted with an output of response data from the access request x1 through a response bus 270 as one unit, and therefore a detailed description of the same processing will be omitted.

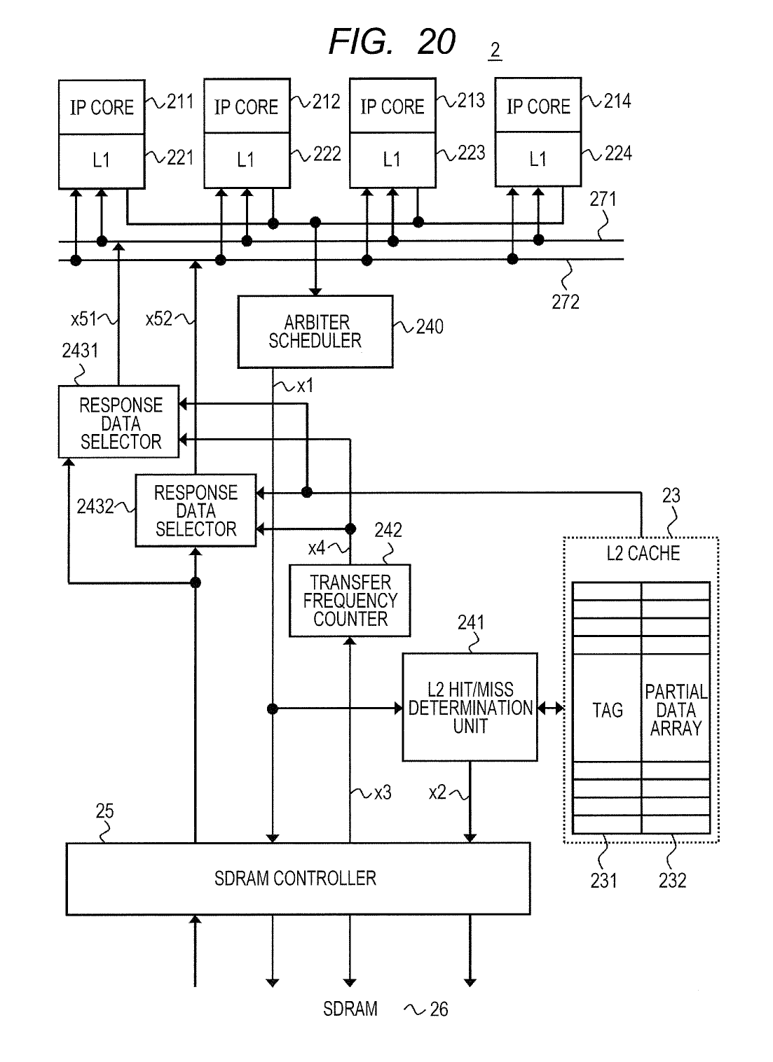

FIG. 20 is a block diagram illustrating a configuration of the memory control device 2 in a multiprocessor according to a fourth embodiment of the present invention. The memory control device 2 includes the IP cores 211 to 214, the L1 caches 221 to 224, an L2 cache 23, an arbiter scheduler 240, an L2 HIT/MISS determination unit 241, a transfer number counter 242, response data selectors 2431, 2432, the SDRAM controller 25, and the SDRAM 26.

The L2 cache 23 stores a tag 231 and a partial data array 232 as in FIG. 1. In FIG. 20, the response data selectors are doubled as compared with FIG. 29, and coupled to respective response buses 271 and 272.

That is, in FIG. 20, data transfer from the L2 cache 23 and data transfer from the SDRAM 26 are convolved, and respond doubly, thereby enabling throughput of the entire memory control device 2 to be improved. In this case, there is a need to supply different data to a plurality of IPs at the same time by doubling as with the response buses 271, 272, and the response buses 271, 272.

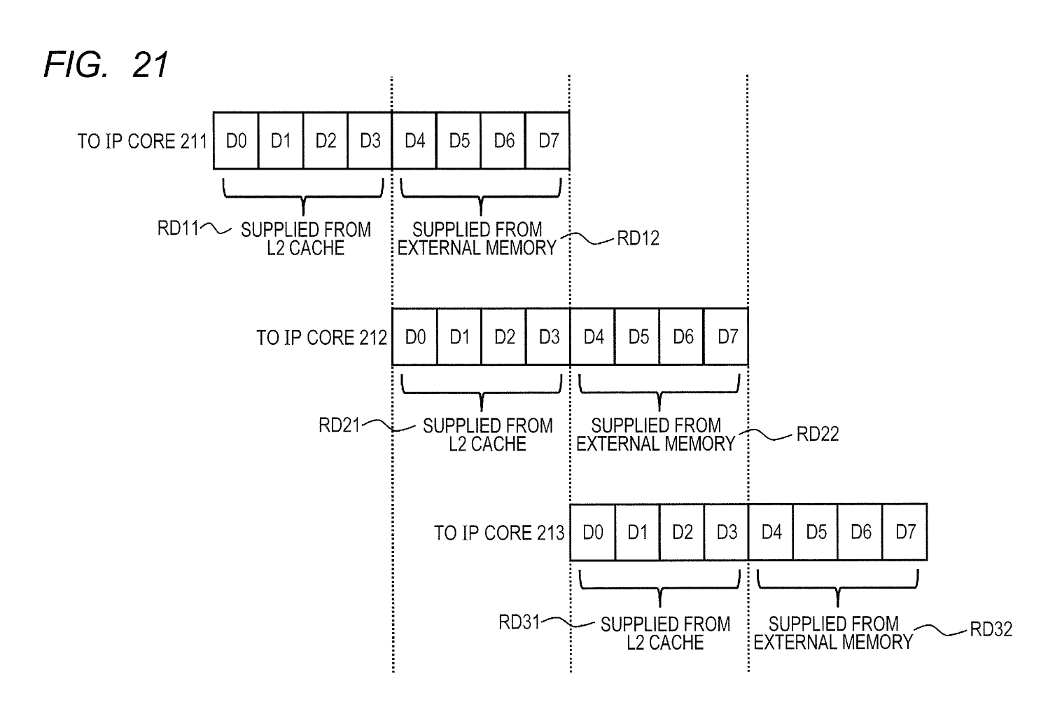

Thus, in the fourth embodiment of the present invention, a multicore SoC having the plurality of IP cores is assumed as illustrated in FIG. 20. In this configuration, the IP cores 211 to 214 can conduct the memory access request, independently. The memory control device 2 of FIG. 20 can supply those requests from the L2 cache and the external memory in a pipeline manner as illustrated in FIG. 21.

The memory control device 2 determines the hit/miss of the L2 cache 23 in response to the requests from the respective IP cores, and supplies data corresponding to the external memory latency from the L2 cache 23 if a hit occurs. Therefore, because data is supplied from the external memory, an access port of the L2 cache 23 becomes free.

FIG. 21 is a diagram illustrating the effects of the L2 cache hit according to the fourth embodiment of the present invention. In an example of FIG. 21, the memory control device 2 supplies data D0 to D3 (data group RD11) from the L2 cache 23 in response to the request of the IP core 211. Thereafter, since D4 and subsequent data (data group RD12) are supplied from the external memory (SDRAM 26), the memory control device 2 can supply the data D0 to D3 (data group RD21) from the L2 cache 23 in response to a request of the IP core 212. That is, supply, of the data group RD21 read from the partial data array 232 of the L2 cache 23 and the data group RD22 read from the SDRAM 26 to the IP core 212 starts while the data group RD12 is being supplied to the IP core 211. Accordingly, during this time, simultaneous data supply can be conducted from the external memory to the IP core 211, and from the L2 cache 23 to the IP core 212. Hence, the memory throughput can be doubled while the latency of the external memory is hidden. Likewise, the IP core 213 can supply the data group RD31 from the L2 cache 23 when the IP core 212 supplies the data group from the external memory.

In other words, the control unit according to the fourth embodiment of the present invention conducts the hit determination in response to the second access request received from the second processor core after receiving the first access request from the first processor core. If the result of the hit determination responsive to the second access request is the cache hit, the control unit reads the part of data from the second memory in response to the second access request, and outputs the part of data to the second processor core, while reading data from the third memory to output the data to the first processor core.

### Fifth Embodiment

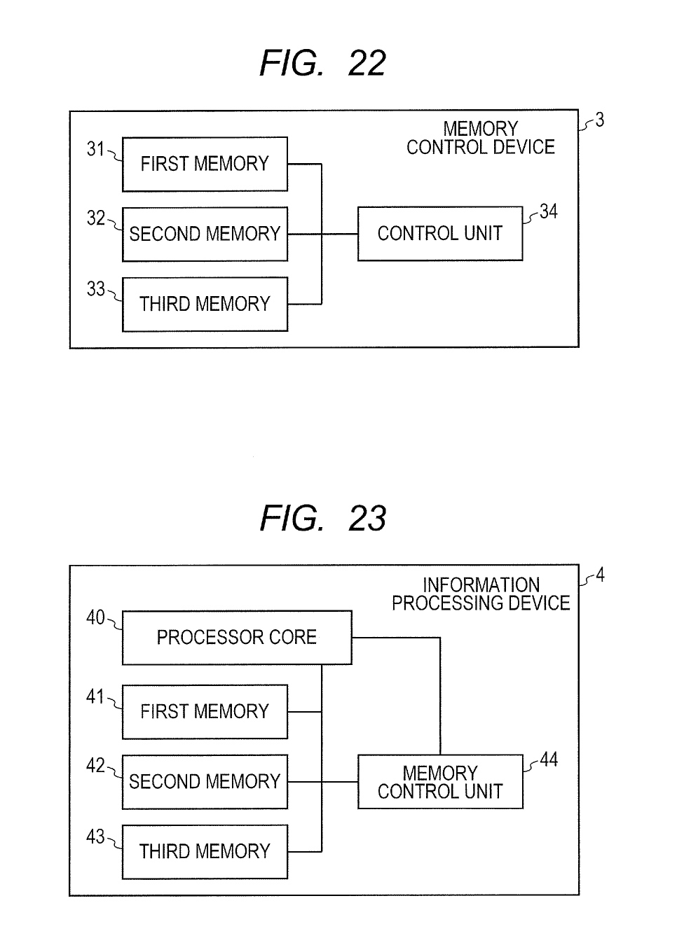

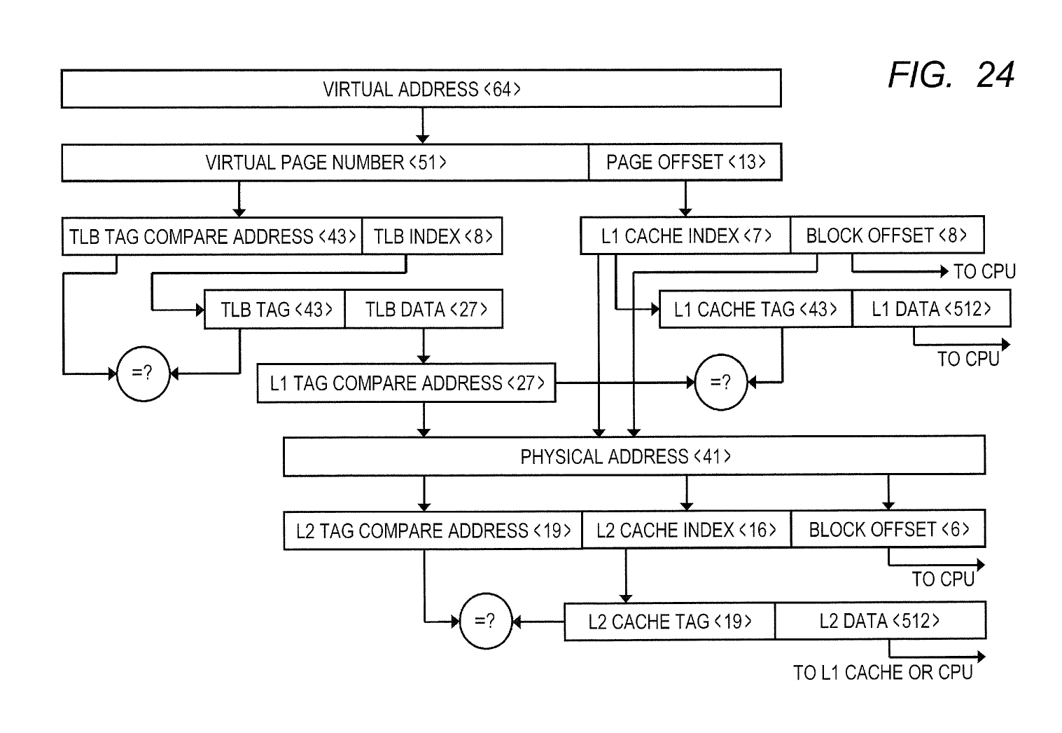

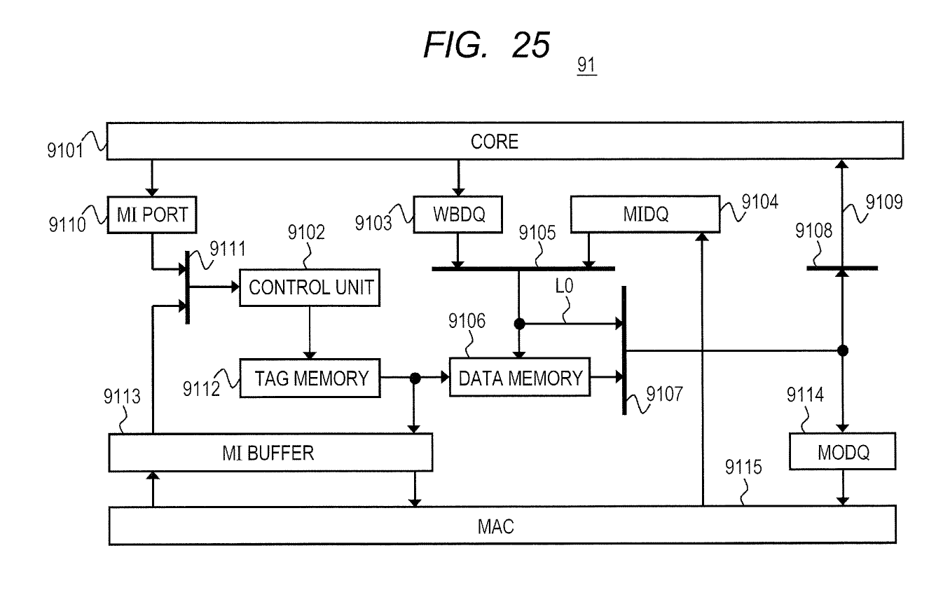

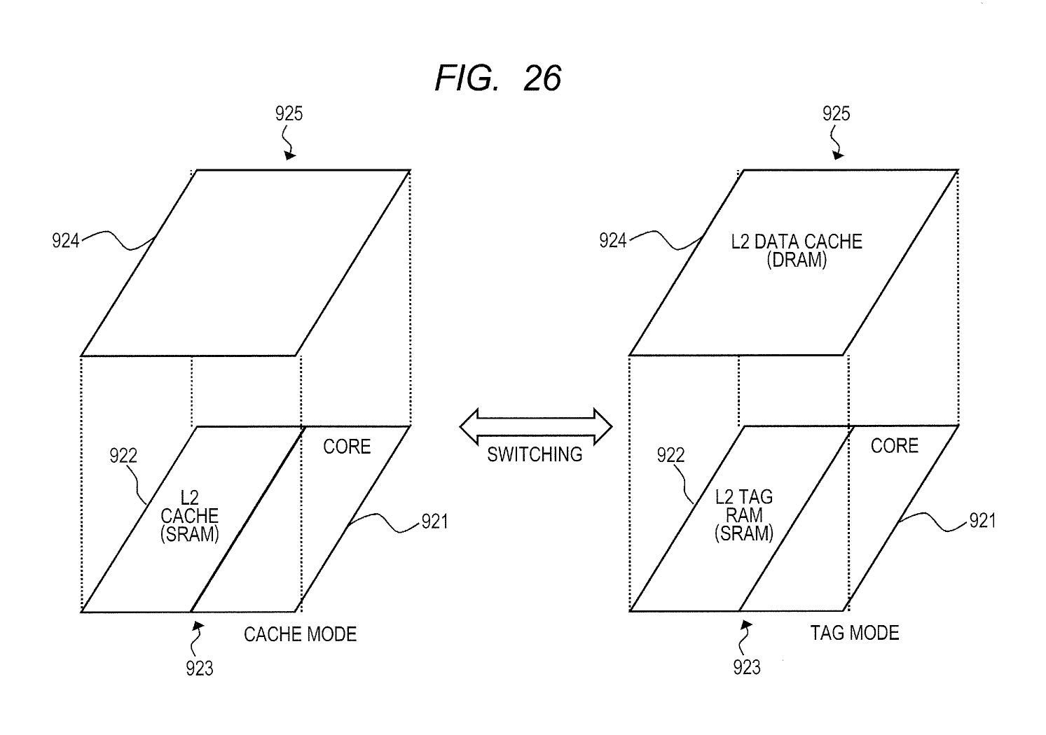

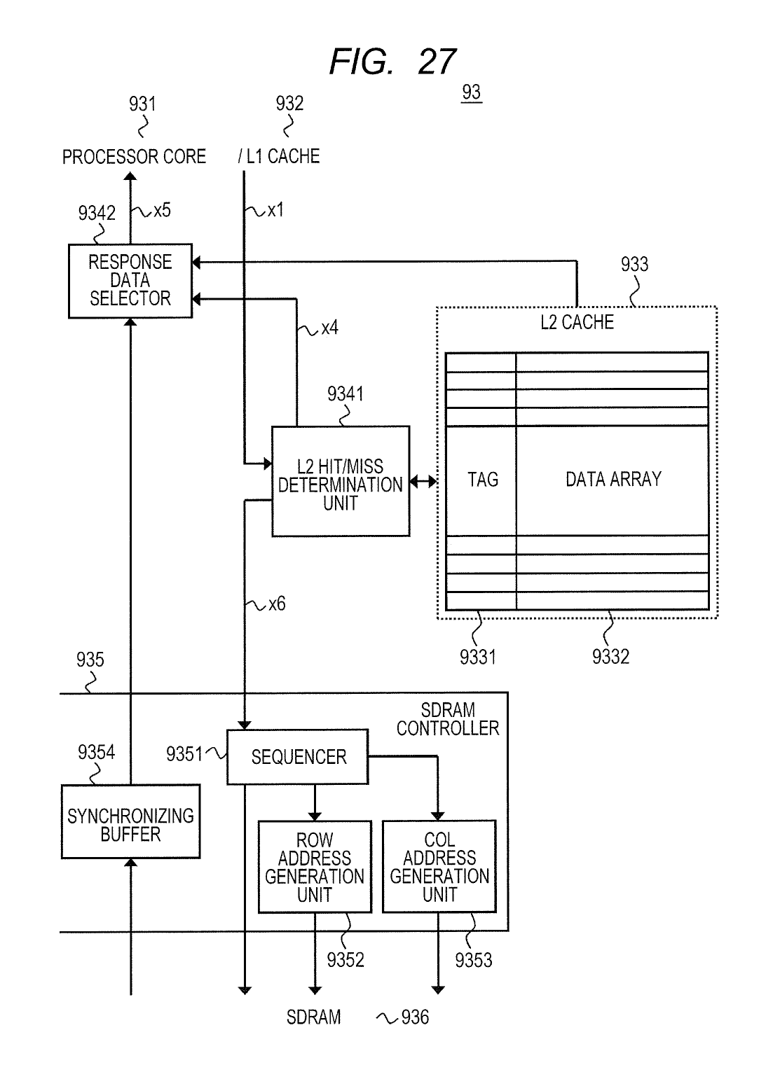

In a fifth embodiment of the present invention, a minimum configuration of the present invention will be described. FIG. 22 is a block diagram illustrating a configuration of a memory control device 3 according to the fifth embodiment of the present invention. The memory control device 3 includes a first memory 31 which is a cache memory of a given hierarchy, a second memory 32 which is a cache memory of a lower level hierarchy than that of at least the first memory 31, a third memory 33 which is a lower level hierarchy than that of at least the second memory 32, and longer in a delay time since start-up until a real data access than that of the first memory 31 and the second memory 32, and a control unit 34 that controls the input and output of the first memory 31, the second memory 32, and the third memory 33. In this example, the second memory 32 stores at least a part of data in each data string among a plurality of data strings with a given number of pieces of data as a unit. Also, the third memory 33 stores all of the data within the plurality of data strings. If a cache miss occurs in the first memory 31, the control unit 34 conducts the hit determination of the cache in the second memory 32, and starts an access to the third memory 33. Then, if the result of the hit determination is the cache hit, the control unit 34 reads the part of data falling under the cache hit from the second memory 32 as leading head, and reads data in the data string to which the part of data belongs other than the part of data from the third memory 33, and responds as the subsequent data of the leading data.

That is, the L2 cache or a last level cache (LLC) (LLC) (second memory 32) located at a last stage positioned before the main memory (third memory 33) functions to hide the access latency of a main memory, for example, the external DRAM. The second memory 32 stores only a part of the data which is stored in the L1 (first memory 31) of the IP core such as a CPU when reading and writing. The partial data is mainly positioned at a head of the cache, and basically defined as a portion to be first accessed, and only the data positioned at the head of the cache is not always stored.

If an L1 cache miss occurs in each of the IP cores, both of the L2 cache and the external DRAM start to be accessed at the same time. Under the circumstances, during a time corresponding to the latency of the external DRAM, the latency of the memory access when the L1 cache miss occurs is reduced by supplying data from the L2 cache and subsequently from the external DRAM in a relay manner, and the memory capacity required for the L2 cache is reduced at the same time.

The L2 cache stores only a part of the data stored in the L1 cache of the IP core such as the CPU when reading and writing. When the L1 cache miss occurs, both of the L2 cache and the external DRAM start at the same time, and during the time corresponding to the latency of the external DRAM, data is supplied from the L2 cache and subsequently from the external DRAM in the relay manner. As a result, the latency of the memory access is reduced, and the memory capacity required for the last level cache is reduced.

Thus, if a cache hit occurs in the second memory, a part of data within the second memory is used as the leading data, and the remaining data in the same data string within the third memory is used as the subsequent data to take the integrity of the response data. In this example, the second memory and the third memory are different in response speed from each other. A part of data from the second memory responds at high speed as in the related art, but the remaining data from the third memory has a latency. Under the circumstances, when the access to the third memory starts together with the hit determination of the second memory, a delay of the response time of the third memory can be complemented by a time during which a part of data is read from the second memory. With the above configuration, the same latency as that when a response is made by only the second memory can be maintained with the use of the second memory and the third memory which are different in the response speed from each other. In this case, the second memory has only to store a part of data in the data string where the cache hit occurs at minimum, that is, only data which configures leading portion of data when making a response. Hence, the amount of data to be stored can be reduced while maintaining the same cache hit ratio in the second memory as that in the related art. That is, the memory capacity of the second memory can be reduced.

The type of the above-mentioned third memory 33 is no object. For example, the third memory 33 may be an SRAM, a DRAM, an HDD, or a flash memory.

### Sixth Embodiment of the Invention

FIG. 23 is a block diagram illustrating a configuration of an information processing apparatus 4 according to a sixth embodiment of the present invention. The information processing apparatus 4 includes a processor core 40, a first memory 41 which is a cache memory of a given hierarchy, a second memory 42 which is a cache memory of a lower level hierarchy than that of at least the first memory 41, a third memory 43 which is a lower level hierarchy than that of at least the second memory 42, and longer in a delay time since start-up until a real data access than that of the first memory 41 and the second memory 42, and a control unit 44 that controls the input and output of the first memory 41, the second memory 42, and the third memory 43. In this example, the second memory 42 stores at least a part of data in each data string among a plurality of data strings with a given number of pieces of data as a unit. The third memory 43 stores all of the data within the plurality of data strings. If a cache miss occurs in the first memory 41, the control unit 44 conducts the hit determination of the cache in the second memory 42, and starts an access to the third memory 33 in response to the access request from the processor core 40. If the result of the hit determination is the cache hit, the control unit 34 reads the part of data falling under the cache hit from the second memory 42 as leading head, and reads data in the data string to which the part of data belongs other than the part of data from the third memory 43, and responds as the subsequent data of the leading data.

According to the sixth embodiment of the present invention, if a hit occurs in the second level cache (second memory 42), data of a leading portion of the data string where a hit occurs is output from the second level cache, and during this time, the remaining data is output from the external memory (third memory 43). For that reason, the data string where a miss occurs in the first level cache at first can be output to the processor core 40 with the help of the data output from the second level cache and the data output from the external memory. Because it takes time to read data from the external memory, data is read from the second level cache higher in read speed than the external memory during the read time of the external memory. As a result, it can be realized to reduce the latency as if all of the data in the data string is read from the second level cache. Because only a part of each data string is held in the second level cache in advance, it can be realized to reduce the capacity of the second level cache at the same time. The amount of capacity reduction does not affect the size of the tag memory in the second level cache, the hit ratio of the second level cache can be also maintained, and the reduction of the latency as a whole can be realized.

### Other Embodiments of the Invention

The present invention can be applied to a processor having a hierarchical cache memory, and a SoC (system on a chip) into which the processor or the other hardware IP is integrated.

Also, the other embodiment of the present invention can be expressed as follows. That is, there is provided an information processing apparatus including a plurality of memory hierarchies, in which when a read request is made from a memory of a higher level hierarchy to a memory of a lower level hierarchy, the read request is made to the plurality of memory hierarchies located in the lower level hierarchy, and data is configured in the order of a response to respond to the memory read request of the higher level hierarchy.

Also, in the above information processing apparatus, memory access order of the lower level hierarchy is determined whether a specific memory hierarchy holds a copy of data of a partial data hierarchy in a lower level hierarchy than the specific memory hierarchy, or not.

Further, in the above information processing apparatus, when the write request is made from a memory of the higher level hierarchy to a memory of the lower level hierarchy, data is stored in a memory of a specific hierarchy until a timing at which data can be injected into the memory of the lower level hierarchy, and data is written directly into the lower level hierarchical memory after the timing, and a part of the data is again written into the memory of the lower level hierarchy when the data is evicted from the memory of the specific hierarchy. Furthermore, in the above information processing apparatus, particularly, the memory of the lower level hierarchy is a DRAM.

The present invention is not limited to the above embodiments, but can be appropriately changed without departing from the scope of the invention.

What is claimed is:

1. A memory control device, comprising:
a first memory that is a cache memory of a given hierarchy;
a second memory that is a cache memory of a lower level hierarchy than that of at least the first memory;
a third memory that is a lower level hierarchy than that of at least the second memory, and longer in delay time since start-up until an actual data access than the first memory and the second memory; and
a control unit that controls input and output of the first memory, the second memory, and the third memory,
wherein the second memory stores at least a part of data from each data string among a plurality of data strings with given number of data as a unit,
wherein the third memory stores all of data within the plurality of data strings therein,
wherein if a cache miss occurs in the first memory, the control unit conducts hit determination of a cache in the second memory, and starts an access to the third memory, and
wherein if the result of the hit determination is a cache hit, the control unit reads the part of data falling under the cache hit from the second memory as leading data, reads data other than the part of data, of a data string to which the part of data belongs, from the third memory, and makes a response as subsequent data to the leading data.

2. The memory control device according to claim 1,
wherein the part of data has the amount of data which is continuously read from the second memory since an access to the third memory starts until first data is read.

3. The memory control device according to claim 1,
wherein the second memory stores the part of data in a larger number of data strings than that when all of the data within each data string is stored.

4. The memory control device according to claim 1,
wherein the third memory reads the data on the basis of a first request for starting an access, and a second request for designating a data position to be read in the access within the data string,
wherein the control unit issues the first request to the third memory together with the hit determination in the second memory,
wherein if the result of the hit determination is the cache hit, the control unit designates data subsequent to the part of data in a data string falling under the cache hit as the data position, and issues the second request to the third memory, and
wherein if the result of the hit determination is the cache miss, the control unit designates all of data strings falling under the cache miss as the data position, and issues the second request to the third memory.

5. The memory control device according to claim 1,
wherein the control unit writes, in response to a request for writing a specific data string, a part of data in the specific data string into the second memory, and writes data other than the part of data in the specific data string into the third memory, and
wherein after writing the data into the third memory, the control unit writes the part of data written into the second memory, into the third memory.

6. The memory control device according to claim 1,
wherein the second memory further stores partial tag information indicative of a data position of the part of data within the data string,
wherein the control unit determines, in response to an access request including designation of a specific data position to be preferentially output within the data string, that the cache hit occurs when the partial tag information corresponds to the designated data position, and
wherein if the result of the hit determination is the cache hit, the control unit reads the part of data corresponding to the partial tag information falling under the cache bit, from the second memory as the leading data.

7. The memory control device according to claim 1,
wherein the control unit conducts the hit determination in response to a second access request received from a second processor core after receiving a first access request from a first processor core, and
wherein if the determination of the hit determination in response to the second access request is the cache hit, the control unit reads the part of data based on the second access request from the second memory to output the read data to the second processor core while reading data from the third memory to output the read data to the first processor core.

8. The memory control device according to claim 1,
wherein the third memory is a DRAM.

9. A memory control method in a memory control device, including: a first memory that is a cache memory of a given hierarchy; a second memory that is a cache memory of a lower level hierarchy than that of at least the first memory; and a third memory that is a lower level hierarchy than that of at least the second memory, longer in delay time since start-up until an actual data access than the first memory and the second memory, and stores all of, data within the plurality of data strings therein, the method comprising:
if a cache miss occurs in the first memory, conducting hit determination of a cache in the second memory;
starting an access to the third memory together with the hit determination; and
if the result of the hit determination is a cache hit, reading the part of data falling under the cache hit from the second memory as leading data, reading data other than the part of data, of a data string to which the part of data belongs, from the third memory, and making a response as subsequent data to the leading data.

10. An information processing apparatus, comprising:
a processor core;
a first memory that is a cache memory of a given hierarchy;
a second memory that is a cache memory of a lower level hierarchy than that of at least the first memory;
a third memory that is a lower level hierarchy than that of at least the second memory, and longer in delay time since start-up until an actual data access than the first memory and the second memory; and
a control unit that controls input and output of the first memory, the second memory, and the third memory,
wherein the second memory stores at least a part of data from each data string among a plurality of data strings with a given number of data as a unit,
wherein the third memory stores all of data within the plurality of data strings therein,
wherein if a cache miss occurs in the first memory, the control unit conducts hit determination of a cache in the second memory, and starts an access to the third memory, and
wherein if the result of the hit determination is a cache hit, the control unit reads the part of data falling under the cache hit from the second memory as leading data, reads data other than the part of data, of a data string to which the part of data belongs, from the third memory, and makes a response as subsequent data to the leading data.

11. A memory control device, comprising:
a first cache memory;
a second cache memory that is a lower level hierarchy of at least the first cache memory; and
an external memory that is a lower level hierarchy of at least the first cache memory,
wherein if a hit determination result of a cache in the second cache memory is a cache hit, the second cache memory and the external memory are memories of the same hierarchy, and
wherein the hit determination result is a cache miss, the external memory is a lower level hierarchy of the second cache memory.

12. A memory control device having three or more memory hierarchies,
wherein if a cache miss occurs in a cache memory of a high level hierarchy, an access request is made to memories of a plurality of hierarchies which are lower level hierarchies than the hierarchy of the cache memory at the same time, and
wherein response data is responsive to the access request in the order of data response.
